(19) United States
(12) Patent Application Publication
(10) Pub. No.: US 2022/0336686 A1
(43) Pub. Date: Oct. 20, 2022

(54) PHOTOVOLTAIC MODULE WITH TEXTURED SUPERSTRATE PROVIDING SHINGLE-MIMICKING APPEARANCE

(71) Applicant: GAF Energy LLC, Parsippany, NJ (US)

(72) Inventors: Richard Perkins, San Jose, CA (US); Alex Sharenko, Berkeley, CA (US); Thierry Nguyen, San Francisco, CA (US); Gabriela Bunea, San Jose, CA (US); Anna Wojtowicz, San Francisco, CA (US)

(21) Appl. No.: 17/719,129

(22) Filed: Apr. 12, 2022

Related U.S. Application Data
(60) Provisional application No. 63/174,845, filed on Apr. 14, 2021.

(51) Int. Cl. H01L 31/0236; H01L 31/048; H02S 20/23

(52) U.S. Cl. CPC H01L 31/02366; H01L 31/0481; H02S 20/23

(57) ABSTRACT

A photovoltaic module having at least one solar cell having a plurality of cell fingers, with the fingers arranged in a first grain pattern extending in a first direction. The photovoltaic module includes a frontsheet having a polymer layer. A surface of the polymer layer includes a plurality of indentations arranged in a second grain pattern extending in a second direction. The arrangement of the second grain pattern relative to the arrangement of the first grain pattern imparts no viewable interference pattern of the photovoltaic module.

### CROSS-REFERENCE TO RELATED APPLICATION

This application is a Section 111(a) application relating to and claiming the benefit of commonly-owned, co-pending U.S. Provisional Patent Application Ser. No. 63/174,845, filed Apr. 14, 2021, entitled “PHOTOVOLTAIC MODULE WITH TEXTURED SUPERSTRATE PROVIDING SHINGLE-MIMICKING APPEARANCE,” the contents of which are incorporated herein by reference in its entirety.

### FIELD OF THE INVENTION

The present invention relates to roof-integrated photovoltaic modules. More particularly, the present invention relates to roof-integrated photovoltaic modules with textured portions providing a non-uniform or randomized appearance, and roofing systems including such modules.

### BACKGROUND

Solar modules can be placed on building roofs (e.g., residential roofs) to generate electricity. One obstacle to mass-market adoption of solar roofing is poor aesthetics. Standard rack-mounted photovoltaic systems have a very different appearance than traditional roofing materials (e.g., asphalt shingles, wooden shingles, slate shingles, etc.), which can draw unwanted attention. Another aesthetic issue is viewable interference fringe patterns Moiré patterns) created by offset layers of the photovoltaic system and the cell fingers of the solar cells.

### SUMMARY

In some embodiments, a photovoltaic module includes at least one solar cell, wherein the at least one solar cell includes a plurality of cell fingers, wherein the plurality of cell fingers are arranged in a first grain pattern extending in a first direction; an encapsulant encapsulating the at least one solar cell; and a frontsheet juxtaposed with the encapsulant, wherein the frontsheet includes a glass layer having a first surface, a polymer layer having a first surface and a second surface opposite the first surface of the polymer layer, wherein the second surface of the polymer layer is attached to the first surface of the glass layer, wherein the first surface of the polymer layer includes a plurality of indentations, and wherein the plurality of indentations is arranged in a second grain pattern extending in a second direction, wherein the first surface of the polymer layer forms an upper surface of the photovoltaic module, and wherein the arrangement of the second grain pattern relative to the arrangement of the first grain pattern imparts no viewable interference pattern of the photovoltaic module.

In some embodiments, the cell fingers have a pitch of 1.0 mm to 1.5 mm. In some embodiments, a majority of the plurality of indentations have a length of 1.2 mm to 1.4 mm. In some embodiments, a majority of the plurality of indentations have a width of 2.85 mm to 2.95 mm. In some embodiments, a majority of the plurality of indentations includes a depth of 0.17 mm to 0.28 mm. In some embodiments, the second direction is zero degrees relative to the first direction. In some embodiments, the second direction is 45 degrees relative to the first direction. In some embodiments, the second direction is 90 degrees relative to the first direction.

In some embodiments, a majority of the plurality of indentations have a length of 1.44 mm to 1.52 mm. In some embodiments, a majority of the plurality of indentations have a width of 3.19 mm to 3.24 mm. In some embodiments, a majority of the plurality of indentations have a depth of 0.19 mm to 0.32 mm. In some embodiments, the second direction is zero degrees relative to the first direction. In some embodiments, the second direction is 45 degrees relative to the first direction. In some embodiments, the second direction is 90 degrees relative to the first direction.

In some embodiments, a system includes a plurality of photovoltaic modules installed on a roof deck, wherein each of the photovoltaic modules includes at least one solar cell, wherein the at least one solar cell includes a plurality of cell fingers, wherein the plurality of cell fingers are arranged in a first grain pattern extending in a first direction; an encapsulant encapsulating the at least one solar cell; and a frontsheet juxtaposed with the encapsulant, wherein the frontsheet includes a glass layer having a first surface, a polymer layer having a first surface and a second surface opposite the first surface of the polymer layer, wherein the second surface of the polymer layer is attached to the first surface of the glass layer, wherein the first surface of the polymer layer includes a plurality of indentations, and wherein the plurality of indentations is arranged in a second grain pattern extending in a second direction, wherein the first surface of the polymer layer forms an upper surface of the photovoltaic module, and wherein the arrangement of the second grain pattern relative to the arrangement of the first grain pattern imparts no viewable interference pattern of the photovoltaic modules.

In some embodiments, the cell fingers include a pitch of 1.0 mm to 1.5 mm. In some embodiments, a majority of the plurality of indentations have a length of 1.2 mm to 1.52 mm, wherein the majority of the plurality of indentations have a width of 2.85 mm to 3.24 mm, and wherein the majority of the plurality of indentations have a depth of 0.17 mm to 0.32 mm. In some embodiments, the second direction is zero degrees relative to the first direction. In some embodiments, the second direction is 45 degrees relative to the first direction. In some embodiments, the second direction is 90 degrees relative to the first direction.

### BRIEF DESCRIPTION OF DRAWINGS

FIG. 1 shows a schematic view of an embodiment of a photovoltaic module;

FIGS. 2A through 2C show embodiments of a textured release liner employed by the photovoltaic module shown in FIG. 1;

FIG. 3 shows an embodiment of a solar cell employed by the photovoltaic module shown in FIG. 1;

FIGS. 4A through 4C show embodiments of a photovoltaic module including the textured release liner shown in FIG. 2A;

FIGS. 5A through 5C show embodiments of a photovoltaic module including the textured release liner shown in FIG. 2B; and

FIGS. 6A through 6C show embodiments of a photovoltaic module including the textured release liner shown in FIG. 2C.

### DETAILED DESCRIPTION

The present invention will be further explained with reference to the attached drawings, wherein like structures are referred to by like numerals throughout the several views. The drawings shown are not necessarily to scale, with emphasis instead generally being placed upon illustrating the principles of the present invention. Further, some features may be exaggerated to show details of particular components.

The figures constitute a part of this specification and include illustrative embodiments of the present invention and illustrate various objects and features thereof. Further, the figures are not necessarily to scale, some features may be exaggerated to show details of particular components. In addition, any measurements, specifications and the like shown in the figures are intended to be illustrative, and not restrictive. Therefore, specific structural and functional details disclosed herein are not to be interpreted as limiting, but merely as a representative basis for teaching one skilled in the art to variously employ the present invention.

Among those benefits and improvements that have been disclosed, other objects and advantages of this invention will become apparent from the following description taken in conjunction with the accompanying figures. Detailed embodiments of the present invention are disclosed herein; however, it is to be understood that the disclosed embodiments are merely illustrative of the invention that may be embodied in various forms. In addition, each of the examples given in connection with the various embodiments of the invention which are intended to be illustrative, and not restrictive.

Throughout the specification and claims, the following terms take the meanings explicitly associated herein, unless the context clearly dictates otherwise. The phrases “in one embodiment” and “in some embodiments” as used herein do not necessarily refer to the same embodiment(s), though they may. Furthermore, the phrases “in another embodiment” and “in some other embodiments” as used herein do not necessarily refer to a different embodiment, although they may. Thus, as described below, various embodiments of the invention may be readily combined, without departing from the scope or spirit of the invention.

The term “based on” is not exclusive and allows for being based on additional factors not described, unless the context clearly dictates otherwise. In addition, throughout the specification, the meaning of “a,” “an,” and “the” include plural references. The meaning of “in” includes “in” and “on.” The term “majority” as used herein is defined as more than fifty percent (50%).

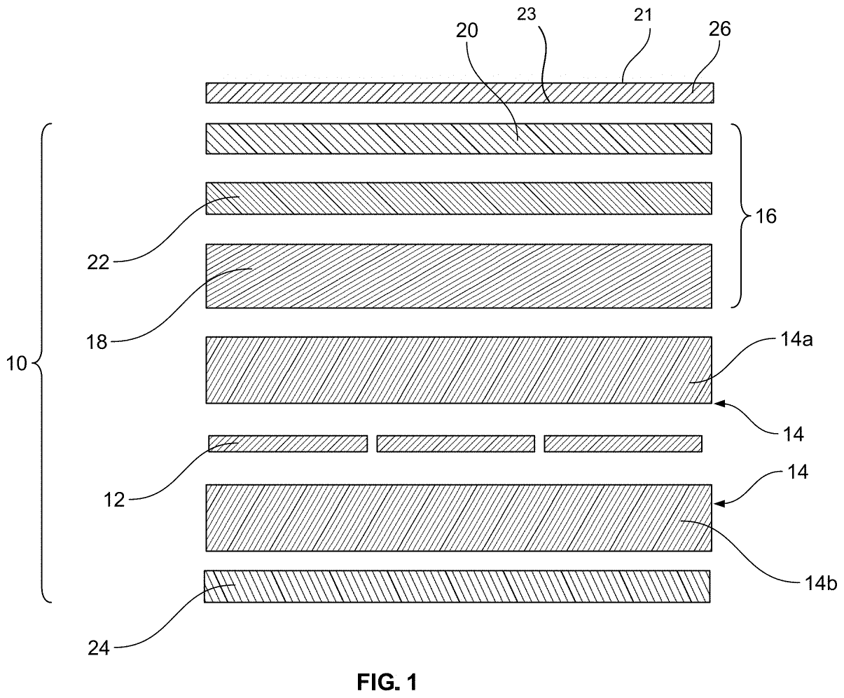

Referring to FIG. 1, in an embodiment, a photovoltaic module 10 includes at least one solar cell 12, an encapsulant 14 encapsulating the at least one solar cell 12, and a frontsheet 16 juxtaposed with the encapsulant 14. As used herein, the terms “encapsulating” and “encapsulates” mean to partially or fully envelope or enclose, and with respect to certain embodiments of the photovoltaic module 10, the at least one solar cell 12 is fully enveloped by or enclosed within the encapsulant 14, or partially enveloped by or enclosed within the encapsulant 14. In an embodiment, the encapsulant 14 includes a first layer 14a and a second layer 14b.

In an embodiment, the encapsulant 14 may be made from polyolefins, ethyl vinyl acetates, ionomers, silicones, poly vinyl butyral, epoxies, polyurethanes, or combinations/hybrids thereof. In an embodiment, the encapsulant 14 is made from thermosetting polyolefin.

In an embodiment, the encapsulant 14 includes a thickness of 0.4 mm to 1.8 mm. In another embodiment, the encapsulant 14 includes a thickness of 0.4 mm to 1.7 mm. In another embodiment, the encapsulant 14 includes a thickness of 0.4 mm to 1.6 mm. In another embodiment, the encapsulant 14 includes a thickness of 0.4 mm to 1.5 mm. In another embodiment, the encapsulant 14 includes a thickness of 0.4 mm to 1.4 mm. In another embodiment, the encapsulant 14 includes a thickness of 0.4 mm to 1.3 mm. In another embodiment, the encapsulant 14 includes a thickness of 0.4 mm to 1.2 mm. In another embodiment, the encapsulant 14 includes a thickness of 0.4 mm to 1.1 mm. In another embodiment, the encapsulant 14 includes a thickness of 0.4 mm to 1.0 mm. In another embodiment, the encapsulant 14 includes a thickness of 0.4 mm to 0.9 mm. In another embodiment, the encapsulant 14 includes a thickness of 0.4 mm to 0.8 mm. In another embodiment, the encapsulant 14 includes a thickness of 0.4 mm to 0.7 mm. In another embodiment, the encapsulant 14 includes a thickness of 0.4 mm to 0.6 mm. In another embodiment, the encapsulant 14 includes a thickness of 0.4 mm to 0.5 mm.

In an embodiment, the encapsulant 14 includes a thickness of 0.5 mm to 1.8 mm. In another embodiment, the encapsulant 14 includes a thickness of 0.5 mm to 1.7 mm. In another embodiment, the encapsulant 14 includes a thickness of 0.5 mm to 1.6 mm. In another embodiment, the encapsulant 14 includes a thickness of 0.5 mm to 1.5 mm. In another embodiment, the encapsulant 14 includes a thickness of 0.5 mm to 1.4 mm. In another embodiment, the encapsulant 14 includes a thickness of 0.5 mm to 1.3 mm. In another embodiment, the encapsulant 14 includes a thickness of 0.5 mm to 1.2 mm. In another embodiment, the encapsulant 14 includes a thickness of 0.5 mm to 1.1 mm. In another embodiment, the encapsulant 14 includes a thickness of 0.5 mm to 1.0 mm. In another embodiment, the encapsulant 14 includes a thickness of 0.5 mm to 0.9 mm. In another embodiment, the encapsulant 14 includes a thickness of 0.5 mm to 0.8 mm. In another embodiment, the encapsulant 14 includes a thickness of 0.5 mm to 0.7 mm. In another embodiment, the encapsulant 14 includes a thickness of 0.5 mm to 0.6 mm.

In an embodiment, the encapsulant 14 includes a thickness of 0.6 mm to 1.8 mm. In another embodiment, the encapsulant 14 includes a thickness of 0.6 mm to 1.7 mm. In another embodiment, the encapsulant 14 includes a thickness of 0.6 mm to 1.6 mm. In another embodiment, the encapsulant 14 includes a thickness of 0.6 mm to 1.5 mm. In another embodiment, the encapsulant 14 includes a thickness of 0.6 mm to 1.4 mm. In another embodiment, the encapsulant 14 includes a thickness of 0.6 mm to 1.3 mm. In another embodiment, the encapsulant 14 includes a thickness of 0.6 mm to 1.2 mm. In another embodiment, the encapsulant 14 includes a thickness of 0.6 mm to 1.1 mm. In another embodiment, the encapsulant 14 includes a thickness of 0.6 mm to 1.0 mm. In another embodiment, the encapsulant 14 includes a thickness of 0.6 mm to 0.9 mm. In another embodiment, the encapsulant 14 includes a thickness of 0.6 mm to 0.8 mm. In another embodiment, the encapsulant 14 includes a thickness of 0.6 mm to 0.7 mm.

In an embodiment, the encapsulant 14 includes a thickness of 0.7 mm to 1.8 mm. In another embodiment, the encapsulant 14 includes a thickness of 0.7 mm to 1.7 mm. In another embodiment, the encapsulant 14 includes a thickness of 0.7 mm to 1.6 mm. In another embodiment, the encapsulant 14 includes a thickness of 0.7 mm to 1.5 mm. In another embodiment, the encapsulant 14 includes a thickness of 0.7 mm to 1.4 mm. In another embodiment, the encapsulant 14 includes a thickness of 0.7 mm to 1.3 mm. In another embodiment, the encapsulant 14 includes a thickness of 0.7 mm to 1.2 mm. In another embodiment, the encapsulant 14 includes a thickness of 0.7 mm to 1.1 mm. In another embodiment, the encapsulant 14 includes a thickness of 0.7 mm to 1.0 mm. In another embodiment, the encapsulant 14 includes a thickness of 0.7 mm to 0.9 mm. In another embodiment, the encapsulant 14 includes a thickness of 0.7 mm to 0.8 mm.

In an embodiment, the encapsulant 14 includes a thickness of 0.8 mm to 1.8 mm. In another embodiment, the encapsulant 14 includes a thickness of 0.8 mm to 1.7 mm. In another embodiment, the encapsulant 14 includes a thickness of 0.8 mm to 1.6 mm. In another embodiment, the encapsulant 14 includes a thickness of 0.8 mm to 1.5 mm. In another embodiment, the encapsulant 14 includes a thickness of 0.8 mm to 1.4 mm. In another embodiment, the encapsulant 14 includes a thickness of 0.8 mm to 1.3 mm. In another embodiment, the encapsulant 14 includes a thickness of 0.8 mm to 1.2 mm. In another embodiment, the encapsulant 14 includes a thickness of 0.8 mm to 1.1 mm. In another embodiment, the encapsulant 14 includes a thickness of 0.8 mm to 1.0 mm. In another embodiment, the encapsulant 14 includes a thickness of 0.8 mm to 0.9 mm.

In an embodiment, the encapsulant 14 includes a thickness of 0.9 mm to 1.8 mm. In another embodiment, the encapsulant 14 includes a thickness of 0.9 mm to 1.7 mm. In another embodiment, the encapsulant 14 includes a thickness of 0.9 mm to 1.6 mm. In another embodiment, the encapsulant 14 includes a thickness of 0.9 mm to 1.5 mm. In another embodiment, the encapsulant 14 includes a thickness of 0.9 mm to 1.4 mm. In another embodiment, the encapsulant 14 includes a thickness of 0.9 mm to 1.3 mm. In another embodiment, the encapsulant 14 includes a thickness of 0.9 mm to 1.2 mm. In another embodiment, the encapsulant 14 includes a thickness of 0.9 mm to 1.1 mm. In another embodiment, the encapsulant 14 includes a thickness of 0.9 mm to 1.0 mm.

In an embodiment, the encapsulant 14 includes a thickness of 1.0 mm to 1.8 mm. In another embodiment, the encapsulant 14 includes a thickness of 1.0 mm to 1.7 mm. In another embodiment, the encapsulant 14 includes a thickness of 1.0 mm to 1.6 mm. In another embodiment, the encapsulant 14 includes a thickness of 1.0 mm to 1.5 mm. In another embodiment, the encapsulant 14 includes a thickness of 1.0 mm to 1.4 mm. In another embodiment, the encapsulant 14 includes a thickness of 1.0 mm to 1.3 mm. In another embodiment, the encapsulant 14 includes a thickness of 1.0 mm to 1.2 mm. In another embodiment, the encapsulant 14 includes a thickness of 1.0 mm to 1.1 mm.

In an embodiment, the encapsulant 14 includes a thickness of 1.1 mm to 1.8 mm. In another embodiment, the encapsulant 14 includes a thickness of 1.1 mm to 1.7 mm. In another embodiment, the encapsulant 14 includes a thickness of 1.1 mm to 1.6 mm. In another embodiment, the encapsulant 14 includes a thickness of 1.1 mm to 1.5 mm. In another embodiment, the encapsulant 14 includes a thickness of 1.1 mm to 1.4 mm. In another embodiment, the encapsulant 14 includes a thickness of 1.1 mm to 1.3 mm. In another embodiment, the encapsulant 14 includes a thickness of 1.1 mm to 1.2 mm.

In an embodiment, the encapsulant 14 includes a thickness of 1.2 mm to 1.8 mm. In another embodiment, the encapsulant 14 includes a thickness of 1.2 mm to 1.7 mm. In another embodiment, the encapsulant 14 includes a thickness of 1.2 mm to 1.6 mm. In another embodiment, the encapsulant 14 includes a thickness of 1.2 mm to 1.5 mm. In another embodiment, the encapsulant 14 includes a thickness of 1.2 mm to 1.4 mm. In another embodiment, the encapsulant 14 includes a thickness of 1.2 mm to 1.3 mm.

In an embodiment, the encapsulant 14 includes a thickness of 1.3 mm to 1.8 mm. In another embodiment, the encapsulant 14 includes a thickness of 1.3 mm to 1.7 mm. In another embodiment, the encapsulant 14 includes a thickness of 1.3 mm to 1.6 mm. In another embodiment, the encapsulant 14 includes a thickness of 1.3 mm to 1.5 mm. In another embodiment, the encapsulant 14 includes a thickness of 1.3 mm to 1.4 mm.

In an embodiment, the encapsulant 14 includes a thickness of 1.4 mm to 1.8 mm. In another embodiment, the encapsulant 14 includes a thickness of 1.4 mm to 1.7 mm. In another embodiment, the encapsulant 14 includes a thickness of 1.4 mm to 1.6 mm. In another embodiment, the encapsulant 14 includes a thickness of 1.4 mm to 1.5 mm.

In an embodiment, the encapsulant 14 includes a thickness of 1.5 mm to 1.8 mm. In another embodiment, the encapsulant 14 includes a thickness of 1.5 mm to 1.7 mm. In another embodiment, the encapsulant 14 includes a thickness of 1.5 mm to 1.6 mm. In an embodiment, the encapsulant 14 includes a thickness of 1.6 mm to 1.8 mm. In another embodiment, the encapsulant 14 includes a thickness of 1.6 mm to 1.7 mm. In an embodiment, the encapsulant 14 includes a thickness of 1.7 mm to 1.8 mm. In an embodiment, the encapsulant 14 includes a thickness of 0.4 mm. In an embodiment, the encapsulant 14 includes a thickness of 0.5 mm. In an embodiment, the encapsulant 14 includes a thickness of 0.6 mm. In an embodiment, the encapsulant 14 includes a thickness of 0.7 mm. In an embodiment, the encapsulant 14 includes a thickness of 0.8 mm. In an embodiment, the encapsulant 14 includes a thickness of 0.9 mm. In an embodiment, the encapsulant 14 includes a thickness of 1.0 mm. In an embodiment, the encapsulant 14 includes a thickness of 1.1 mm. In an embodiment, the encapsulant 14 includes a thickness of 1.2 mm. In an embodiment, the encapsulant 14 includes a thickness of 1.3 mm. In an embodiment, the encapsulant 14 includes a thickness of 1.4 mm. In an embodiment, the encapsulant 14 includes a thickness of 1.5 mm. In an embodiment, the encapsulant 14 includes a thickness of 1.6 mm. In an embodiment, the encapsulant 14 includes a thickness of 1.7 mm. In an embodiment, the encapsulant 14 includes a thickness of 1.8 mm.

In an embodiment, the first layer 14a of the encapsulant 14 includes a thickness of 0.2 mm to 0.9 mm. In another embodiment, the first layer 14a of the encapsulant 14 includes a thickness of 0.2 mm to 0.8 mm. In another embodiment, the first layer 14a of the encapsulant 14 includes a thickness of 0.2 mm to 0.7 mm. In another embodiment, the first layer 14a of the encapsulant 14 includes a thickness of 0.2 mm to 0.6 mm. In another embodiment, the first layer 14a of the encapsulant 14 includes a thickness of 0.2 mm to 0.5 mm. In another embodiment, the first layer 14a of the encapsulant 14 includes a thickness of 0.2 mm to 0.4 mm. In another embodiment, the first layer 14a of the encapsulant 14 includes a thickness of 0.2 mm to 0.3 mm.

In an embodiment, the first layer 14a of the encapsulant 14 includes a thickness of 0.3 mm to 0.9 mm. In another embodiment, the first layer 14a of the encapsulant 14 includes a thickness of 0.3 mm to 0.8 mm. In another embodiment, the first layer 14a of the encapsulant 14 includes a thickness of 0.3 mm to 0.7 mm. In another embodiment, the first layer 14a of the encapsulant 14 includes a thickness of 0.3 mm to 0.6 mm. In another embodiment, the first layer 14a of the encapsulant 14 includes a thickness of 0.3 mm to 0.5 mm. In another embodiment, the first layer 14a of the encapsulant 14 includes a thickness of 0.3 mm to 0.4 mm.

In an embodiment, the first layer 14a of the encapsulant 14 includes a thickness of 0.4 mm to 0.9 mm. In another embodiment, the first layer 14a of the encapsulant 14 includes a thickness of 0.4 mm to 0.8 mm. In another embodiment, the first layer 14a of the encapsulant 14 includes a thickness of 0.4 mm to 0.7 mm. In another embodiment, the first layer 14a of the encapsulant 14 includes a thickness of 0.4 mm to 0.6 mm. In another embodiment, the first layer 14a of the encapsulant 14 includes a thickness of 0.4 mm to 0.5 mm.

In an embodiment, the first layer 14a of the encapsulant 14 includes a thickness of 0.5 mm to 0.9 mm. In another embodiment, the first layer 14a of the encapsulant 14 includes a thickness of 0.5 mm to 0.8 mm. In another embodiment, the first layer 14a of the encapsulant 14 includes a thickness of 0.5 mm to 0.7 mm. In another embodiment, the first layer 14a of the encapsulant 14 includes a thickness of 0.5 mm to 0.6 mm. In an embodiment, the first layer 14a of the encapsulant 14 includes a thickness of 0.6 mm to 0.9 mm. In another embodiment, the first layer 14a of the encapsulant 14 includes a thickness of 0.6 mm to 0.8 mm. In another embodiment, the first layer 14a of the encapsulant 14 includes a thickness of 0.6 mm to 0.7 mm. In an embodiment, the first layer 14a of the encapsulant 14 includes a thickness of 0.7 mm to 0.9 mm. In another embodiment, the first layer 14a of the encapsulant 14 includes a thickness of 0.7 mm to 0.8 mm. In an embodiment, the first layer 14a of the encapsulant 14 includes a thickness of 0.8 mm to 0.9 mm.

In an embodiment, the second layer 14b of the encapsulant 14 includes a thickness of 0.2 mm to 0.9 mm. In another embodiment, the second layer 14b of the encapsulant 14 includes a thickness of 0.2 mm to 0.8 mm. In another embodiment, the second layer 14b of the encapsulant 14 includes a thickness of 0.2 mm to 0.7 mm. In another embodiment, the second layer 14b of the encapsulant 14 includes a thickness of 0.2 mm to 0.6 mm. In another embodiment, the second layer 14b of the encapsulant 14 includes a thickness of 0.2 mm to 0.5 mm. In another embodiment, the second layer 14b of the encapsulant 14 includes a thickness of 0.2 mm to 0.4 mm. In another embodiment, the second layer 14b of the encapsulant 14 includes a thickness of 0.2 mm to 0.3 mm.

In an embodiment, the second layer 14b of the encapsulant 14 includes a thickness of 0.3 mm to 0.9 mm. In another embodiment, the second layer 14b of the encapsulant 14 includes a thickness of 0.3 mm to 0.8 mm. In another embodiment, the second layer 14b of the encapsulant 14 includes a thickness of 0.3 mm to 0.7 mm. In another embodiment, the second layer 14b of the encapsulant 14 includes a thickness of 0.3 mm to 0.6 mm. In another embodiment, the second layer 14b of the encapsulant 14 includes a thickness of 0.3 mm to 0.5 mm. In another embodiment, the second layer 14b of the encapsulant 14 includes a thickness of 0.3 mm to 0.4 mm.

In an embodiment, the second layer 14b of the encapsulant 14 includes a thickness of 0.4 mm to 0.9 mm. In another embodiment, the second layer 14b of the encapsulant 14 includes a thickness of 0.4 mm to 0.8 mm. In another embodiment, the second layer 14b of the encapsulant 14 includes a thickness of 0.4 mm to 0.7 mm. In another embodiment, the second layer 14b of the encapsulant 14 includes a thickness of 0.4 mm to 0.6 mm. In another embodiment, the second layer 14b of the encapsulant 14 includes a thickness of 0.4 mm to 0.5 mm.

In an embodiment, the second layer 14b of the encapsulant 14 includes a thickness of 0.5 mm to 0.9 mm. In another embodiment, the second layer 14b of the encapsulant 14 includes a thickness of 0.5 mm to 0.8 mm. In another embodiment, the second layer 14b of the encapsulant 14 includes a thickness of 0.5 mm to 0.7 mm. In another embodiment, the second layer 14b of the encapsulant 14 includes a thickness of 0.5 mm to 0.6 mm. In an embodiment, the second layer 14b of the encapsulant 14 includes a thickness of 0.6 mm to 0.9 mm. In another embodiment, the second layer 14b of the encapsulant 14 includes a thickness of 0.6 mm to 0.8 mm. In another embodiment, the second layer 14b of the encapsulant 14 includes a thickness of 0.6 mm to 0.7 mm. In an embodiment, the second layer 14b of the encapsulant 14 includes a thickness of 0.7 mm to 0.9 mm. In another embodiment, the second layer 14b of the encapsulant 14 includes a thickness of 0.7 mm to 0.8 mm. In an embodiment, the second layer 14b of the encapsulant 14 includes a thickness of 0.8 mm to 0.9 mm.

In an embodiment, the thickness of the first layer 14a is equal to the thickness of the second layer 14b. In another embodiment, the thickness of the first layer 14a is different from the thickness of the second layer 14b.

In an embodiment, the frontsheet 16 includes a glass layer 18 and a polymer layer 20 attached to the glass layer 18. In an embodiment, the frontsheet 16 is juxtaposed with the first layer 14a of the encapsulant 14. In an embodiment, each of the glass layer 18 and the polymer layer 20 is transparent.

In some embodiments, the polymer layer 20 includes a first surface 21 and a second surface 23 opposite the first surface 21. In some embodiments, the first surface 21 of the polymer layer 20 is an upper surface of the photovoltaic module 10.

In an embodiment, the glass layer 18 includes a thickness of 2.5 mm to 4 mm. In another embodiment, the glass layer 18 includes a thickness of 2.5 mm to 3.5 mm. In another embodiment, the glass layer 18 includes a thickness of 2.5 mm to 3 mm. In another embodiment, the glass layer 18 includes a thickness of 3 mm to 4 mm. In another embodiment, the glass layer 18 includes a thickness of 3.5 mm to 4 mm. In another embodiment, the glass layer 18 includes a thickness of 2.6 mm to 3.5 mm. In another embodiment, the glass layer 18 includes a thickness of 2.7 mm to 3.5 mm. In another embodiment, the glass layer 18 includes a thickness of 2.8 mm to 3.5 mm. In another embodiment, the glass layer 18 includes a thickness of 2.9 mm to 3.5 mm. In another embodiment, the glass layer 18 includes a thickness of 3 mm to 3.5 mm. In another embodiment, the glass layer 18 includes a thickness of 3.1 mm to 3.5 mm. In another embodiment, the glass layer 18 includes a thickness of 3.2 mm to 3.5 mm. In another embodiment, the glass layer 18 includes a thickness of 3.3 mm to 3.5 mm. In another embodiment, the glass layer 18 includes a thickness of 3.4 mm to 3.5 mm. In another embodiment, the glass layer 18 includes a thickness of 2.5 mm to 3.4 mm. In another embodiment, the glass layer 18 includes a thickness of 2.5 mm to 3.3 mm. In another embodiment, the glass layer 18 includes a thickness of 2.5 mm to 3.2 mm. In another embodiment, the glass layer 18 includes a thickness of 2.5 mm to 3.1 mm. In another embodiment, the glass layer 18 includes a thickness of 2.5 mm to 2.9 mm. In another embodiment, the glass layer 18 includes a thickness of 2.5 mm to 2.8 mm. In another embodiment, the glass layer 18 includes a thickness of 2.5 mm to 2.7 mm. In another embodiment, the glass layer 18 includes a thickness of 2.5 mm to 2.6 mm.

In another embodiment, the glass layer 18 includes a thickness of 2.5 mm. In another embodiment, the glass layer 18 includes a thickness of 2.6 mm. In another embodiment, the glass layer 18 includes a thickness of 2.7 mm. In another embodiment, the glass layer 18 includes a thickness of 2.8 mm. In another embodiment, the glass layer 18 includes a thickness of 2.9 mm. In another embodiment, the glass layer 18 includes a thickness of 3 mm. In another embodiment, the glass layer 18 includes a thickness of 3.1 mm. In another embodiment, the glass layer 18 includes a thickness of 3.2 mm. In another embodiment, the glass layer 18 includes a thickness of 3.3 mm. In another embodiment, the glass layer 18 includes a thickness of 3.4 mm. In another embodiment, the glass layer 18 includes a thickness of 3.5 mm. In another embodiment, the glass layer 18 includes a thickness of 3.6 mm. In another embodiment, the glass layer 18 includes a thickness of 3.7 mm. In another embodiment, the glass layer 18 includes a thickness of 3.8 mm. In another embodiment, the glass layer 18 includes a thickness of 3.9 mm. In another embodiment, the glass layer 18 includes a thickness of 4 mm.

In an embodiment, the polymer layer 20 is attached to the glass layer 18 by an adhesive layer 22. In an embodiment, the adhesive layer 22 may include polyvinyl butyrate, acrylic, silicone, or polycarbonate. In another embodiment, the adhesive layer 22 may include pressure sensitive adhesives. In another embodiment, the polymer layer 20 is attached to the glass layer 18 by thermal bonding. In another embodiment, the frontsheet 16 includes at least one of the glass layer 18 or the polymer layer 20.

In an embodiment, the adhesive layer 22 includes thermosetting polyolefin, thermosetting polyolefin encapsulant material, thermosetting ethylene-vinyl acetate (EVA), EVA encapsulants, thermoplastic olefin, thermoplastic polyolefin (TPO) or hybrids/combinations thereof.

In an embodiment, the adhesive layer 22 includes a thickness of 1 μm to 900 μm. In an embodiment, the adhesive layer 22 includes a thickness of 1 μm to 900 μm. In an embodiment, the adhesive layer 22 includes a thickness of 1 μm to 850 μm. In an embodiment, the adhesive layer 22 includes a thickness of 1 μm to 800 μm. In an embodiment, the adhesive layer 22 includes a thickness of 1 μm to 750 μm. In an embodiment, the adhesive layer 22 includes a thickness of 1 μm to 700 μm. In an embodiment, the adhesive layer 22 includes a thickness of 1 μm to 650 μm. In an embodiment, the adhesive layer 22 includes a thickness of 1 μm to 600 μm. In an embodiment, the adhesive layer 22 includes a thickness of 1 μm to 550 μm. In an embodiment, the adhesive layer 22 includes a thickness of 1 μm to 500 μm. In an embodiment, the adhesive layer 22 includes a thickness of 1 μm to 450 μm. In an embodiment, the adhesive layer 22 includes a thickness of 1 μm to 400 μm. In an embodiment, the adhesive layer 22 includes a thickness of 1 μm to 350 μm. In an embodiment, the adhesive layer 22 includes a thickness of 1 μm to 300 μm. In an embodiment, the adhesive layer 22 includes a thickness of 1 μm to 250 μm. In an embodiment, the adhesive layer 22 includes a thickness of 1 μm to 200 μm. In an embodiment, the adhesive layer 22 includes a thickness of 1 μm to 150 μm. In an embodiment, the adhesive layer 22 includes a thickness of 1 μm to 100 μm. In an embodiment, the adhesive layer 22 includes a thickness of 1 μm to 50 μm.

In an embodiment, the adhesive layer 22 includes a thickness of 50 μm to 900 μm. In an embodiment, the adhesive layer 22 includes a thickness of 50 μm to 850 μm. In an embodiment, the adhesive layer 22 includes a thickness of 50 μm to 800 μm. In an embodiment, the adhesive layer 22 includes a thickness of 50 μm to 750 μm. In an embodiment, the adhesive layer 22 includes a thickness of 50 μm to 700 μm. In an embodiment, the adhesive layer 22 includes a thickness of 50 μm to 650 μm. In an embodiment, the adhesive layer 22 includes a thickness of 50 μm to 600 μm. In an embodiment, the adhesive layer 22 includes a thickness of 50 μm to 550 μm. In an embodiment, the adhesive layer 22 includes a thickness of 50 μm to 500 μm. In an embodiment, the adhesive layer 22 includes a thickness of 50 μm to 450 μm. In an embodiment, the adhesive layer 22 includes a thickness of 50 μm to 400 μm. In an embodiment, the adhesive layer 22 includes a thickness of 50 μm to 350 μm. In an embodiment, the adhesive layer 22 includes a thickness of 50 μm to 300 μm. In an embodiment, the adhesive layer 22 includes a thickness of 50 μm to 250 μm. In an embodiment, the adhesive layer 22 includes a thickness of 50 μm to 200 μm. In an embodiment, the adhesive layer 22 includes a thickness of 50 μm to 150 μm. In an embodiment, the adhesive layer 22 includes a thickness of 50 μm to 100 μm.

In an embodiment, the adhesive layer 22 includes a thickness of 100 μm to 900 μm. In an embodiment, the adhesive layer 22 includes a thickness of 100 μm to 850 μm. In an embodiment, the adhesive layer 22 includes a thickness of 100 μm to 800 μm. In an embodiment, the adhesive layer 22 includes a thickness of 100 μm to 750 μm. In an embodiment, the adhesive layer 22 includes a thickness of 100 μm to 700 μm. In an embodiment, the adhesive layer 22 includes a thickness of 100 μm to 650 μm. In an embodiment, the adhesive layer 22 includes a thickness of 100 μm to 600 μm. In an embodiment, the adhesive layer 22 includes a thickness of 100 μm to 550 μm. In an embodiment, the adhesive layer 22 includes a thickness of 100 μm to 500 μm. In an embodiment, the adhesive layer 22 includes a thickness of 100 μm to 450 μm. In an embodiment, the adhesive layer 22 includes a thickness of 100 μm to 400 μm. In an embodiment, the adhesive layer 22 includes a thickness of 100 μm to 350 μm. In an embodiment, the adhesive layer 22 includes a thickness of 100 μm to 300 μm. In an embodiment, the adhesive layer 22 includes a thickness of 100 μm to 250 μm. In an embodiment, the adhesive layer 22 includes a thickness of 100 μm to 200 μm. In an embodiment, the adhesive layer 22 includes a thickness of 100 μm to 150 μm.

In an embodiment, the adhesive layer 22 includes a thickness of 150 μm to 900 μm. In an embodiment, the adhesive layer 22 includes a thickness of 150 μm to 850 μm. In an embodiment, the adhesive layer 22 includes a thickness of 150 μm to 800 μm. In an embodiment, the adhesive layer 22 includes a thickness of 150 μm to 750 μm. In an embodiment, the adhesive layer 22 includes a thickness of 150 μm to 700 μm. In an embodiment, the adhesive layer 22 includes a thickness of 150 μm to 650 μm. In an embodiment, the adhesive layer 22 includes a thickness of 150 μm to 600 μm. In an embodiment, the adhesive layer 22 includes a thickness of 150 μm to 550 μm. In an embodiment, the adhesive layer 22 includes a thickness of 150 μm to 500 μm. In an embodiment, the adhesive layer 22 includes a thickness of 150 μm to 450 μm. In an embodiment, the adhesive layer 22 includes a thickness of 150 μm to 400 μm. In an embodiment, the adhesive layer 22 includes a thickness of 150 μm to 350 μm. In an embodiment, the adhesive layer 22 includes a thickness of 150 μm to 300 μm. In an embodiment, the adhesive layer 22 includes a thickness of 150 μm to 250 μm. In an embodiment, the adhesive layer 22 includes a thickness of 150 μm to 200 μm.

In an embodiment, the adhesive layer 22 includes a thickness of 200 μm to 900 μm. In an embodiment, the adhesive layer 22 includes a thickness of 200 μm to 850 μm. In an embodiment, the adhesive layer 22 includes a thickness of 200 μm to 800 μm. In an embodiment, the adhesive layer 22 includes a thickness of 200 μm to 750 μm. In an embodiment, the adhesive layer 22 includes a thickness of 200 μm to 700 μm. In an embodiment, the adhesive layer 22 includes a thickness of 200 μm to 650 μm. In an embodiment, the adhesive layer 22 includes a thickness of 200 μm to 600 μm. In an embodiment, the adhesive layer 22 includes a thickness of 200 μm to 550 μm. In an embodiment, the adhesive layer 22 includes a thickness of 200 μm to 500 μm. In an embodiment, the adhesive layer 22 includes a thickness of 200 μm to 450 μm. In an embodiment, the adhesive layer 22 includes a thickness of 200 μm to 400 μm. In an embodiment, the adhesive layer 22 includes a thickness of 200 μm to 350 μm. In an embodiment, the adhesive layer 22 includes a thickness of 200 μm to 300 μm. In an embodiment, the adhesive layer 22 includes a thickness of 200 μm to 250 μm.

In an embodiment, the adhesive layer 22 includes a thickness of 250 μm to 900 μm. In an embodiment, the adhesive layer 22 includes a thickness of 250 μm to 850 μm. In an embodiment, the adhesive layer 22 includes a thickness of 250 μm to 800 μm. In an embodiment, the adhesive layer 22 includes a thickness of 250 μm to 750 μm. In an embodiment, the adhesive layer 22 includes a thickness of 250 μm to 700 μm. In an embodiment, the adhesive layer 22 includes a thickness of 250 μm to 650 μm. In an embodiment, the adhesive layer 22 includes a thickness of 250 μm to 600 μm. In an embodiment, the adhesive layer 22 includes a thickness of 250 μm to 550 μm. In an embodiment, the adhesive layer 22 includes a thickness of 250 μm to 500 μm. In an embodiment, the adhesive layer 22 includes a thickness of 250 μm to 450 μm. In an embodiment, the adhesive layer 22 includes a thickness of 250 μm to 400 μm. In an embodiment, the adhesive layer 22 includes a thickness of 250 μm to 350 μm. In an embodiment, the adhesive layer 22 includes a thickness of 250 μm to 300 μm.

In an embodiment, the adhesive layer 22 includes a thickness of 300 μm to 900 μm. In an embodiment, the adhesive layer 22 includes a thickness of 300 μm to 850 μm. In an embodiment, the adhesive layer 22 includes a thickness of 300 μm to 800 μm. In an embodiment, the adhesive layer 22 includes a thickness of 300 μm to 750 μm. In an embodiment, the adhesive layer 22 includes a thickness of 300 μm to 700 μm. In an embodiment, the adhesive layer 22 includes a thickness of 300 μm to 650 μm. In an embodiment, the adhesive layer 22 includes a thickness of 300 μm to 600 μm. In an embodiment, the adhesive layer 22 includes a thickness of 300 μm to 550 μm. In an embodiment, the adhesive layer 22 includes a thickness of 300 μm to 500 μm. In an embodiment, the adhesive layer 22 includes a thickness of 300 μm to 450 μm. In an embodiment, the adhesive layer 22 includes a thickness of 300 μm to 400 μm. In an embodiment, the adhesive layer 22 includes a thickness of 300 μm to 350 μm.

In an embodiment, the adhesive layer 22 includes a thickness of 350 μm to 900 μm. In an embodiment, the adhesive layer 22 includes a thickness of 350 μm to 850 μm. In an embodiment, the adhesive layer 22 includes a thickness of 350 μm to 800 μm. In an embodiment, the adhesive layer 22 includes a thickness of 350 μm to 750 μm. In an embodiment, the adhesive layer 22 includes a thickness of 350 μm to 700 μm. In an embodiment, the adhesive layer 22 includes a thickness of 350 μm to 650 μm. In an embodiment, the adhesive layer 22 includes a thickness of 350 μm to 600 μm. In an embodiment, the adhesive layer 22 includes a thickness of 350 μm to 550 μm. In an embodiment, the adhesive layer 22 includes a thickness of 350 μm to 500 μm. In an embodiment, the adhesive layer 22 includes a thickness of 350 μm to 450 μm. In an embodiment, the adhesive layer 22 includes a thickness of 350 μm to 400 μm.

In an embodiment, the adhesive layer 22 includes a thickness of 400 μm to 900 μm. In an embodiment, the adhesive layer 22 includes a thickness of 400 μm to 850 μm. In an embodiment, the adhesive layer 22 includes a thickness of 400 μm to 800 μm. In an embodiment, the adhesive layer 22 includes a thickness of 400 μm to 750 μm. In an embodiment, the adhesive layer 22 includes a thickness of 400 μm to 700 μm. In an embodiment, the adhesive layer 22 includes a thickness of 400 μm to 650 μm. In an embodiment, the adhesive layer 22 includes a thickness of 400 μm to 600 μm. In an embodiment, the adhesive layer 22 includes a thickness of 400 μm to 550 μm. In an embodiment, the adhesive layer 22 includes a thickness of 400 μm to 500 μm. In an embodiment, the adhesive layer 22 includes a thickness of 400 μm to 450 μm.

In an embodiment, the adhesive layer 22 includes a thickness of 450 μm to 900 μm. In an embodiment, the adhesive layer 22 includes a thickness of 450 μm to 850 μm. In an embodiment, the adhesive layer 22 includes a thickness of 450 μm to 800 μm. In an embodiment, the adhesive layer 22 includes a thickness of 450 μm to 750 μm. In an embodiment, the adhesive layer 22 includes a thickness of 450 μm to 700 μm. In an embodiment, the adhesive layer 22 includes a thickness of 450 μm to 650 μm. In an embodiment, the adhesive layer 22 includes a thickness of 450 μm to 600 μm. In an embodiment, the adhesive layer 22 includes a thickness of 450 μm to 550 μm. In an embodiment, the adhesive layer 22 includes a thickness of 450 μm to 500 μm.

In an embodiment, the adhesive layer 22 includes a thickness of 500 μm to 900 μm. In an embodiment, the adhesive layer 22 includes a thickness of 500 μm to 850 μm. In an embodiment, the adhesive layer 22 includes a thickness of 500 μm to 800 μm. In an embodiment, the adhesive layer 22 includes a thickness of 500 μm to 750 μm. In an embodiment, the adhesive layer 22 includes a thickness of 500 μm to 700 μm. In an embodiment, the adhesive layer 22 includes a thickness of 500 μm to 650 μm. In an embodiment, the adhesive layer 22 includes a thickness of 500 μm to 600 μm. In an embodiment, the adhesive layer 22 includes a thickness of 500 μm to 550 μm.

In an embodiment, the adhesive layer 22 includes a thickness of 550 μm to 900 μm. In an embodiment, the adhesive layer 22 includes a thickness of 550 μm to 850 μm. In an embodiment, the adhesive layer 22 includes a thickness of 550 μm to 800 μm. In an embodiment, the adhesive layer 22 includes a thickness of 550 μm to 750 μm. In an embodiment, the adhesive layer 22 includes a thickness of 550 μm to 700 μm. In an embodiment, the adhesive layer 22 includes a thickness of 550 μm to 650 μm. In an embodiment, the adhesive layer 22 includes a thickness of 550 μm to 600 μm.

In an embodiment, the adhesive layer 22 includes a thickness of 600 μm to 900 μm. In an embodiment, the adhesive layer 22 includes a thickness of 600 μm to 850 μm. In an embodiment, the adhesive layer 22 includes a thickness of 600 μm to 800 μm. In an embodiment, the adhesive layer 22 includes a thickness of 600 μm to 750 μm. In an embodiment, the adhesive layer 22 includes a thickness of 600 μm to 700 μm. In an embodiment, the adhesive layer 22 includes a thickness of 600 μm to 650 μm.

In an embodiment, the adhesive layer 22 includes a thickness of 650 μm to 900 μm. In an embodiment, the adhesive layer 22 includes a thickness of 650 μm to 850 μm. In an embodiment, the adhesive layer 22 includes a thickness of 650 μm to 800 μm. In an embodiment, the adhesive layer 22 includes a thickness of 650 μm to 750 μm. In an embodiment, the adhesive layer 22 includes a thickness of 650 μm to 700 μm. In an embodiment, the adhesive layer 22 includes a thickness of 700 μm to 900 μm. In an embodiment, the adhesive layer 22 includes a thickness of 700 μm to 850 μm. In an embodiment, the adhesive layer 22 includes a thickness of 700 μm to 800 μm. In an embodiment, the adhesive layer 22 includes a thickness of 700 μm to 750 μm. In an embodiment, the adhesive layer 22 includes a thickness of 750 μm to 900 μm. In an embodiment, the adhesive layer 22 includes a thickness of 750 μm to 850 μm. In an embodiment, the adhesive layer 22 includes a thickness of 750 μm to 800 μm. In an embodiment, the adhesive layer 22 includes a thickness of 800 μm to 900 μm. In an embodiment, the adhesive layer 22 includes a thickness of 800 μm to 850 μm. In an embodiment, the adhesive layer 22 includes a thickness of 850 μm to 900 μm.

In an embodiment, the adhesive layer 22 includes a thickness of 1 μm. In an embodiment, the adhesive layer 22 includes a thickness of 50 μm. In an embodiment, the adhesive layer 22 includes a thickness of 100 μm. In an embodiment, the adhesive layer 22 includes a thickness of 1 μm. In an embodiment, the adhesive layer 22 includes a thickness of 150 μm. In an embodiment, the adhesive layer 22 includes a thickness of 200 μm. In an embodiment, the adhesive layer 22 includes a thickness of 250 μm. In an embodiment, the adhesive layer 22 includes a thickness of 300 μm. In an embodiment, the adhesive layer 22 includes a thickness of 350 μm. In an embodiment, the adhesive layer 22 includes a thickness of 400 μm. In an embodiment, the adhesive layer 22 includes a thickness of 450 μm. In an embodiment, the adhesive layer 22 includes a thickness of 500 μm. In an embodiment, the adhesive layer 22 includes a thickness of 550 μm. In an embodiment, the adhesive layer 22 includes a thickness of 600 μm. In an embodiment, the adhesive layer 22 includes a thickness of 650 μm. In an embodiment, the adhesive layer 22 includes a thickness of 700 μm. In an embodiment, the adhesive layer 22 includes a thickness of 750 μm. In an embodiment, the adhesive layer 22 includes a thickness of 800 μm. In an embodiment, the adhesive layer 22 includes a thickness of 850 μm. In an embodiment, the adhesive layer 22 includes a thickness of 900 μm.

In an embodiment, the polymer layer 20 includes a fluoropolymer. In certain embodiments, the fluoropolymer may be ethylene tetrafluoroethylene (ETFE), fluoropolymer is polyvinylidene fluoride (PVDF), tetrafluoroethylene-hexafluoropropylene copolymers (FEP), and tetrafluoroethylene-hexafluoropropylene-vinylidene fluoride copolymers (THV), polyvinyl fluoride (PVF), or blends thereof. In an embodiment, the frontsheet includes fluoropolymers, acrylics, polyesters, silicones, polycarbonates, or combinations thereof. In other embodiments, the polymer layer 20 includes polyethylene terephthalate (PET), polyethylene naphthalate (PEN), polyetheretherketone (PEEK), polyaryletherketone (PAEK), polyarylate (PAR), polyetherimide (PEI), polyarylsulfone (PAS), polyethersulfone (PES), polyamideimide (PAI), polyphenylsulfone (PPSU), polyolefin, cyclic olefin copolymers (CPCs), or polyimide. In an embodiment, the polymer layer 20 includes a crosslinked polymeric material. In an embodiment, 50% to 99% of the polymer chains of the polymeric material are crosslinked.

In an embodiment, the polymer layer 20 includes a thickness of 0.01 mm to 0.5 mm. In another embodiment, the polymer layer 20 includes a thickness of 0.01 mm to 0.4 mm. In another embodiment, the polymer layer 20 includes a thickness of 0.01 mm to 0.3 mm. In another embodiment, the polymer layer 20 includes a thickness of 0.01 mm to 0.2 mm. In another embodiment, the polymer layer 20 includes a thickness of 0.01 mm to 0.1 mm. In another embodiment, the polymer layer 20 includes a thickness of 0.01 mm to 0.09 mm. In another embodiment, the polymer layer 20 includes a thickness of 0.01 mm to 0.08 mm. In another embodiment, the polymer layer 20 includes a thickness of 0.01 mm to 0.07 mm. In another embodiment, the polymer layer 20 includes a thickness of 0.01 mm to 0.06 mm. In another embodiment, the polymer layer 20 includes a thickness of 0.01 mm to 0.05 mm. In another embodiment, the polymer layer 20 includes a thickness of 0.01 mm to 0.04 mm. In another embodiment, the polymer layer 20 includes a thickness of 0.01 mm to 0.03 mm. In another embodiment, the polymer layer 20 includes a thickness of 0.01 mm to 0.02 mm.

In another embodiment, the polymer layer 20 includes a thickness of 0.01 mm to 0.4 mm. In another embodiment, the polymer layer 20 includes a thickness of 0.02 mm to 0.4 mm. In another embodiment, the polymer layer 20 includes a thickness of 0.03 mm to 0.4 mm. In another embodiment, the polymer layer 20 includes a thickness of 0.04 mm to 0.4 mm. In another embodiment, the polymer layer 20 includes a thickness of 0.05 mm to 0.4 mm. In another embodiment, the polymer layer 20 includes a thickness of 0.06 mm to 0.4 mm. In another embodiment, the polymer layer 20 includes a thickness of 0.07 mm to 0.4 mm. In another embodiment, the polymer layer 20 includes a thickness of 0.08 mm to 0.4 mm. In another embodiment, the polymer layer 20 includes a thickness of 0.09 mm to 0.4 mm. In another embodiment, the polymer layer 20 includes a thickness of 0.1 mm to 0.4 mm. In another embodiment, the polymer layer 20 includes a thickness of 0.15 mm to 0.4 mm. In another embodiment, the polymer layer 20 includes a thickness of 0.2 mm to 0.4 mm. In another embodiment, the polymer layer 20 includes a thickness of 0.25 mm to 0.4 mm. In another embodiment, the polymer layer 20 includes a thickness of 0.3 mm to 0.4 mm. In another embodiment, the polymer layer 20 includes a thickness of 0.35 mm to 0.4 mm.

In another embodiment, the polymer layer 20 includes a thickness of 0.025 mm to 0.1 mm. In another embodiment, the polymer layer 20 includes a thickness of 0.03 mm to 0.1 mm. In another embodiment, the polymer layer 20 includes a thickness of 0.035 mm to 0.1 mm. In another embodiment, the polymer layer 20 includes a thickness of 0.04 mm to 0.1 mm. In another embodiment, the polymer layer 20 includes a thickness of 0.045 mm to 0.1 mm. In another embodiment, the polymer layer 20 includes a thickness of 0.05 mm to 0.1 mm. In another embodiment, the polymer layer 20 includes a thickness of 0.06 mm to 0.1 mm. In another embodiment, the polymer layer 20 includes a thickness of 0.065 mm to 0.1 mm. In another embodiment, the polymer layer 20 includes a thickness of 0.07 mm to 0.1 mm. In another embodiment, the polymer layer 20 includes a thickness of 0.075 mm to 0.1 mm. In another embodiment, the polymer layer 20 includes a thickness of 0.08 mm to 0.1 mm. In another embodiment, the polymer layer 20 includes a thickness of 0.085 mm to 0.1 mm. In another embodiment, the polymer layer 20 includes a thickness of 0.09 mm to 0.1 mm. In another embodiment, the polymer layer 20 includes a thickness of 0.095 mm to 0.1 mm.

In an embodiment, a backsheet 24 is juxtaposed with the second layer 14b of the encapsulant 14. In an embodiment, the backsheet 24 includes thermoplastic polyolefin (TPO). In an embodiment, the backsheet 24 includes a single ply TPO roofing membrane. In other embodiments, non-limiting examples of TPO membranes are disclosed in U.S. Pat. No. 9,359,014 to Yang et al., which is incorporated by reference herein in its entirety. In another embodiment, the backsheet 24 includes polyvinyl chloride. In an embodiment, the backsheet 24 includes ethylene propylene diene monomer (EPDM) rubber. In an embodiment, the backsheet 24 includes a flame retardant additive. In some embodiments, the flame retardant additive may be clays, nanoclays, silicas, carbon black, metal hydroxides such as aluminum hydroxide, metal foils, graphite, and combinations thereof.

In an embodiment, the frontsheet 16 is unpainted. In an embodiment, the backsheet 24 is unpainted. In some embodiments, none of the layers of the photovoltaic module 10 is painted. In some embodiments, the frontsheet 16 and the backsheet 24 are unpainted.

In an embodiment, a liner 26 is configured to form a plurality of indentations within the frontsheet 16. In an embodiment, the plurality of indentations is formed within the polymer layer 20 and the adhesive layer 22. In an embodiment, the liner 26 is a textured release liner including a plurality of dimples configured to form the plurality of indentations in the frontsheet 16. In an embodiment, the photovoltaic module 10 is laminated. In an embodiment, the liner 26 is configured to form the plurality of indentations within the frontsheet 16 during lamination of the photovoltaic module 10. In an embodiment, the liner 26 is removed after formation of the plurality of indentations.

In an embodiment, the liner 26 includes a thickness of 0.025 mm to 5 mm. In another embodiment, the liner 26 includes a thickness of 0.025 mm to 4 mm. In another embodiment, the liner 26 includes a thickness of 0.025 mm to 3 mm. In another embodiment, the liner 26 includes a thickness of 0.025 mm to 2 mm. In another embodiment, the liner 26 includes a thickness of 0.025 mm to 1 mm. In another embodiment, the liner 26 includes a thickness of 0.025 mm to 0.5 mm. In an embodiment, the liner 26 includes a thickness of 0.5 mm to 5 mm. In another embodiment, the liner 26 includes a thickness of 0.5 mm to 4 mm. In another embodiment, the liner 26 includes a thickness of 0.5 mm to 3 mm. In another embodiment, the liner 26 includes a thickness of 0.5 mm to 2 mm. In another embodiment, the liner 26 includes a thickness of 0.5 mm to 1 mm.

In an embodiment, the liner 26 includes a thickness of 1 mm to 5 mm. In another embodiment, the liner 26 includes a thickness of 1 mm to 5 mm. In another embodiment, the liner 26 includes a thickness of 1 mm to 4 mm. In another embodiment, the liner 26 includes a thickness of 1 mm to 3 mm. In another embodiment, the liner 26 includes a thickness of 1 mm to 2 mm. In an embodiment, the liner 26 includes a thickness of 2 mm to 5 mm. In another embodiment, the liner 26 includes a thickness of 2 mm to 4 mm. In another embodiment, the liner 26 includes a thickness of 2 mm to 3 mm. In an embodiment, the liner 26 includes a thickness of 3 mm to 5 mm. In another embodiment, the liner 26 includes a thickness of 3 mm to 4 mm. In another embodiment, the liner 26 includes a thickness of 4 mm to 5 mm.

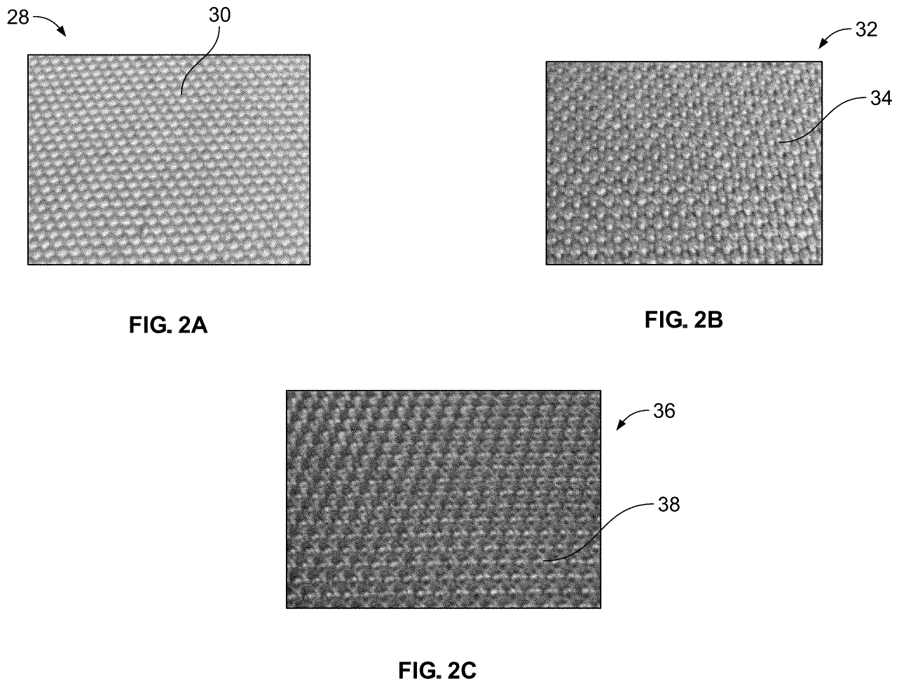

FIGS. 2A through 2C show embodiments of the liner 26. In an embodiment, FIG. 2A shows a liner 28 including a plurality of dimples (i.e., indentations) 30 formed within a surface thereof. In an embodiment, each of the dimples 30 includes a length of 0.95 mm to 1.1 mm. In an embodiment, a majority of the dimples 30 have a length of 0.95 mm to 1.1 mm. In an embodiment, each of the dimples 30 includes a length of 0.95 mm to 1.05 mm. In an embodiment, each of the dimples 30 includes a length of 0.95 mm to 1 mm. In an embodiment, each of the dimples 30 includes a length of 1 mm to 1.1 mm. In an embodiment, each of the dimples 30 includes a length of 1 mm to 1.05 mm. In an embodiment, each of the dimples 30 includes a length of 1.05 mm to 1.1 mm.

In an embodiment, each of the dimples 30 includes a length of 0.95 mm. In an embodiment, each of the dimples 30 includes a length of 0.96 mm. In an embodiment, each of the dimples 30 includes a length of 0.97 mm. In an embodiment, each of the dimples 30 includes a length of 0.98 mm. In an embodiment, each of the dimples 30 includes a length of 0.99 mm. In an embodiment, each of the dimples 30 includes a length of 1 mm. In an embodiment, each of the dimples 30 includes a length of 1.01 mm. In an embodiment, each of the dimples 30 includes a length of 1.02 mm. In an embodiment, each of the dimples 30 includes a length of 1.03 mm. In an embodiment, each of the dimples 30 includes a length of 1.04 mm. In an embodiment, each of the dimples 30 includes a length of 1.05 mm. In an embodiment, each of the dimples 30 includes a length of 1.06 mm. In an embodiment, each of the dimples 30 includes a length of 1.07 mm. In an embodiment, each of the dimples 30 includes a length of 1.08 mm. In an embodiment, each of the dimples 30 includes a length of 1.09 mm. In an embodiment, each of the dimples 30 includes a length of 1.1 mm.

In an embodiment, each of the dimples 30 includes a width of 1.95 mm to 2.1 mm. In an embodiment, a majority of the dimples 30 have a width of 1.95 mm to 2.1 mm. In an embodiment, each of the dimples 30 includes a width of 1.95 mm to 2 mm. In an embodiment, each of the dimples 30 includes a width of 2 mm to 2.1 mm. In an embodiment, each of the dimples 30 includes a width of 1.95 mm. In an embodiment, each of the dimples 30 includes a width of 1.96 mm. In an embodiment, each of the dimples 30 includes a width of 1.97 mm. In an embodiment, each of the dimples 30 includes a width of 1.98 mm. In an embodiment, each of the dimples 30 includes a width of 1.99 mm. In an embodiment, each of the dimples 30 includes a width of 2 mm. In an embodiment, each of the dimples 30 includes a width of 2.01 mm. In an embodiment, each of the dimples 30 includes a width of 2.02 mm. In an embodiment, each of the dimples 30 includes a width of 2.03 mm. In an embodiment, each of the dimples 30 includes a width of 2.04 mm. In an embodiment, each of the dimples 30 includes a width of 2.05 mm. In an embodiment, each of the dimples 30 includes a width of 2.06 mm. In an embodiment, each of the dimples 30 includes a width of 2.07 mm. In an embodiment, each of the dimples 30 includes a width of 2.08 mm. In an embodiment, each of the dimples 30 includes a width of 2.09 mm. In an embodiment, each of the dimples 30 includes a width of 2.1 mm.

In an embodiment, each of the dimples 30 includes a depth of 0.12 mm to 0.2 mm. In an embodiment, a majority of the dimples 30 have a depth of 0.12 mm to 0.2 mm. In an embodiment, each of the dimples 30 includes a depth of 0.12 mm to 0.19 mm. In an embodiment, each of the dimples 30 includes a depth of 0.12 mm to 0.18 mm. In an embodiment, each of the dimples 30 includes a depth of 0.12 mm to 0.17 mm. In an embodiment, each of the dimples 30 includes a depth of 0.12 mm to 0.16 mm. In an embodiment, each of the dimples 30 includes a depth of 0.12 mm to 0.15 mm. In an embodiment, each of the dimples 30 includes a depth of 0.12 mm to 0.14 mm. In an embodiment, each of the dimples 30 includes a depth of 0.12 mm to 0.13 mm.

In an embodiment, each of the dimples 30 includes a depth of 0.13 mm to 0.2 mm. In an embodiment, each of the dimples 30 includes a depth of 0.13 mm to 0.19 mm. In an embodiment, each of the dimples 30 includes a depth of 0.13 mm to 0.18 mm. In an embodiment, each of the dimples 30 includes a depth of 0.13 mm to 0.17 mm. In an embodiment, each of the dimples 30 includes a depth of 0.13 mm to 0.16 mm. In an embodiment, each of the dimples 30 includes a depth of 0.13 mm to 0.15 mm. In an embodiment, each of the dimples 30 includes a depth of 0.13 mm to 0.14 mm.

In an embodiment, each of the dimples 30 includes a depth of 0.14 mm to 0.2 mm. In an embodiment, each of the dimples 30 includes a depth of 0.14 mm to 0.19 mm. In an embodiment, each of the dimples 30 includes a depth of 0.14 mm to 0.18 mm. In an embodiment, each of the dimples 30 includes a depth of 0.14 mm to 0.17 mm. In an embodiment, each of the dimples 30 includes a depth of 0.14 mm to 0.16 mm. In an embodiment, each of the dimples 30 includes a depth of 0.14 mm to 0.15 mm. In an embodiment, each of the dimples 30 includes a depth of 0.15 mm to 0.2 mm. In an embodiment, each of the dimples 30 includes a depth of 0.15 mm to 0.19 mm. In an embodiment, each of the dimples 30 includes a depth of 0.15 mm to 0.18 mm. In an embodiment, each of the dimples 30 includes a depth of 0.15 mm to 0.17 mm. In an embodiment, each of the dimples 30 includes a depth of 0.15 mm to 0.16 mm.

In an embodiment, each of the dimples 30 includes a depth of 0.16 mm to 0.2 mm. In an embodiment, each of the dimples 30 includes a depth of 0.16 mm to 0.19 mm. In an embodiment, each of the dimples 30 includes a depth of 0.16 mm to 0.18 mm. In an embodiment, each of the dimples 30 includes a depth of 0.16 mm to 0.17 mm. In an embodiment, each of the dimples 30 includes a depth of 0.17 mm to 0.2 mm. In an embodiment, each of the dimples 30 includes a depth of 0.17 mm to 0.19 mm. In an embodiment, each of the dimples 30 includes a depth of 0.17 mm to 0.18 mm. In an embodiment, each of the dimples 30 includes a depth of 0.18 mm to 0.2 mm. In an embodiment, each of the dimples 30 includes a depth of 0.18 mm to 0.19 mm. In an embodiment, each of the dimples 30 includes a depth of 0.19 mm to 0.2 mm.

In an embodiment, each of the dimples 30 includes a depth of 0.12 mm. In an embodiment, each of the dimples 30 includes a depth of 0.13 mm. In an embodiment, each of the dimples 30 includes a depth of 0.14 mm. In an embodiment, each of the dimples 30 includes a depth of 0.15 mm. In an embodiment, each of the dimples 30 includes a depth of 0.155 mm. In an embodiment, each of the dimples 30 includes a depth of 0.16 mm. In an embodiment, each of the dimples 30 includes a depth of 0.17 mm. In an embodiment, each of the dimples 30 includes a depth of 0.18 mm. In an embodiment, each of the dimples 30 includes a depth of 0.19 mm.

In an embodiment, the liner 28 includes polytetrafluoroethylene (PTFE). In an embodiment, the liner 28 includes PTFE coated glass fabric. In an embodiment, the PTFE coated glass fabric is Steinbach AG PTFE fabric 345. In an embodiment, the liner 28 is configured to form within the fro sheet 16 a plurality of indentations having a size and shape corresponding to those of the plurality of dimples 30.

In an embodiment, FIG. 2B shows a liner 32 including a plurality of dimples 34 formed within a surface thereof. In an embodiment, each of the dimples 34 includes a length of 1.2 mm to 1.4 mm. In an embodiment, a majority of the dimples 34 have a length of 1.2 mm to 1.4 mm. In an embodiment, each of the dimples 34 includes a length of 1.2 mm to 1.3 mm. In an embodiment, each of the dimples 34 includes a length of 1.3 mm to 1.4 mm. In an embodiment, each of the dimples 34 includes a length of 1.2 mm. In an embodiment, each of the dimples 34 includes a length of 1.3 mm. In an embodiment, each of the dimples 34 includes a length of 1.31 mm. In an embodiment, each of the dimples 34 includes a length of 1.4 mm.

In an embodiment, each of the dimples 34 includes a width of 2.85 mm to 2.95 mm. In an embodiment, a majority of the dimples 34 have a width of 2.85 mm to 2.95 mm. In an embodiment, each of the dimples 34 includes a width of 2.85 mm to 2.9 mm. In an embodiment, each of the dimples 34 includes a width of 2.9 mm to 2.95 mm. In an embodiment, each of the dimples 34 includes a width of 2.85 mm. In an embodiment, each of the dimples 34 includes a width of 2.9 mm. In an embodiment, each of the dimples 34 includes a width of 2.95 mm.

In an embodiment, each of the dimples 34 includes a depth of 0.17 mm to 0.28 mm. In an embodiment, a majority of the dimples 34 have a depth of 0.17 mm to 0.28 mm. In an embodiment, each of the dimples 34 includes a depth of 0.17 mm to 0.27 mm. In an embodiment, each of the dimples 34 includes a depth of 0.17 mm to 0.26 mm. In an embodiment, each of the dimples 34 includes a depth of 0.17 mm to 0.25 mm. In an embodiment, each of the dimples 34 includes a depth of 0.17 mm to 0.24 mm. In an embodiment, each of the dimples 34 includes a depth of 0.17 mm to 0.23 mm. In an embodiment, each of the dimples 34 includes a depth of 0.17 mm to 0.22 mm. In an embodiment, each of the dimples 34 includes a depth of 0.17 mm to 0.21 mm. In an embodiment, each of the dimples 34 includes a depth of 0.17 mm to 0.2 mm. In an embodiment, each of the dimples 34 includes a depth of 0.17 mm to 0.19 mm. In an embodiment, each of the dimples 34 includes a depth of 0.17 mm to 0.18 mm.

In an embodiment, each of the dimples 34 includes a depth of 0.18 mm to 0.28 mm. In an embodiment, each of the dimples 34 includes a depth of 0.18 mm to 0.27 mm. In an embodiment, each of the dimples 34 includes a depth of 0.18 mm to 0.26 mm. In an embodiment, each of the dimples 34 includes a depth of 0.18 mm to 0.25 mm. In an embodiment, each of the dimples 34 includes a depth of 0.18 mm to 0.24 mm. In an embodiment, each of the dimples 34 includes a depth of 0.18 mm to 0.23 mm. In an embodiment, each of the dimples 34 includes a depth of 0.18 mm to 0.22 mm. In an embodiment, each of the dimples 34 includes a depth of 0.18 mm to 0.21 mm. In an embodiment, each of the dimples 34 includes a depth of 0.18 mm to 0.2 mm. In an embodiment, each of the dimples 34 includes a depth of 0.18 mm to 0.19 mm.

In an embodiment, each of the dimples 34 includes a depth of 0.19 mm to 0.28 mm. In an embodiment, each of the dimples 34 includes a depth of 0.19 mm to 0.27 mm. In an embodiment, each of the dimples 34 includes a depth of 0.19 mm to 0.26 mm. In an embodiment, each of the dimples 34 includes a depth of 0.19 mm to 0.25 mm. In an embodiment, each of the dimples 34 includes a depth of 0.19 mm to 0.24 mm. In an embodiment, each of the dimples 34 includes a depth of 0.19 mm to 0.23 mm. In an embodiment, each of the dimples 34 includes a depth of 0.19 mm to 0.22 mm. In an embodiment, each of the dimples 34 includes a depth of 0.19 mm to 0.21 mm. In an embodiment, each of the dimples 34 includes a depth of 0.19 mm to 0.2 mm.

In an embodiment, each of the dimples 34 includes a depth of 0.2 mm to 0.28 mm. In an embodiment, each of the dimples 34 includes a depth of 0.2 mm to 0.27 mm. In an embodiment, each of the dimples 34 includes a depth of 0.2 mm to 0.26 mm. In an embodiment, each of the dimples 34 includes a depth of 0.2 mm to 0.25 mm. In an embodiment, each of the dimples 34 includes a depth of 0.2 mm to 0.24 mm. In an embodiment, each of the dimples 34 includes a depth of 0.2 mm to 0.23 mm. In an embodiment, each of the dimples 34 includes a depth of 0.2 mm to 0.22 mm. In an embodiment, each of the dimples 34 includes a depth of 0.2 mm to 0.21 mm.

In an embodiment, each of the dimples 34 includes a depth of 0.21 mm to 0.28 mm. In an embodiment, each of the dimples 34 includes a depth of 0.21 mm to 0.27 mm. In an embodiment, each of the dimples 34 includes a depth of 0.21 mm to 0.26 mm. In an embodiment, each of the dimples 34 includes a depth of 0.21 mm to 0.25 mm. In an embodiment, each of the dimples 34 includes a depth of 0.21 mm to 0.24 mm. In an embodiment, each of the dimples 34 includes a depth of 0.21 mm to 0.23 mm. In an embodiment, each of the dimples 34 includes a depth of 0.21 mm to 0.22 mm.

In an embodiment, each of the dimples 34 includes a depth of 0.22 mm to 0.28 mm. In an embodiment, each of the dimples 34 includes a depth of 0.22 mm to 0.27 mm. In an embodiment, each of the dimples 34 includes a depth of 0.22 mm to 0.26 mm. In an embodiment, each of the dimples 34 includes a depth of 0.22 mm to 0.25 mm. In an embodiment, each of the dimples 34 includes a depth of 0.22 mm to 0.24 mm. In an embodiment, each of the dimples 34 includes a depth of 0.22 mm to 0.23 mm. In an embodiment, each of the dimples 34 includes a depth of 0.23 mm to 0.28 mm. In an embodiment, each of the dimples 34 includes a depth of 0.23 mm to 0.27 mm. In an embodiment, each of the dimples 34 includes a depth of 0.23 mm to 0.26 mm. In an embodiment, each of the dimples 34 includes a depth of 0.23 mm to 0.25 mm. In an embodiment, each of the dimples 34 includes a depth of 0.23 mm to 0.24 mm.

In an embodiment, each of the dimples 34 includes a depth of 0.24 mm to 0.28 mm. In an embodiment, each of the dimples 34 includes a depth of 0.24 mm to 0.27 mm. In an embodiment, each of the dimples 34 includes a depth of 0.24 mm to 0.26 mm. In an embodiment, each of the dimples 34 includes a depth of 0.24 mm to 0.25 mm. In an embodiment, each of the dimples 34 includes a depth of 0.25 mm to 0.28 mm. In an embodiment, each of the dimples 34 includes a depth of 0.25 mm to 0.27 mm. In an embodiment, each of the dimples 34 includes a depth of 0.25 mm to 0.26 mm. In an embodiment, each of the dimples 34 includes a depth of 0.26 mm to 0.28 mm. In an embodiment, each of the dimples 34 includes a depth of 0.26 mm to 0.27 mm. In an embodiment, each of the dimples 34 includes a depth of 0.27 mm to 0.28 mm.

In an embodiment, each of the dimples 34 includes a depth of 0.17 mm. In an embodiment, each of the dimples 34 includes a depth of 0.18 mm. In an embodiment, each of the dimples 34 includes a depth of 0.19 mm. In an embodiment, each of the dimples 34 includes a depth of 0.2 mm. In an embodiment, each of the dimples 34 includes a depth of 0.21 mm. In an embodiment, each of the dimples 34 includes a depth of 0.22 mm. In an embodiment, each of the dimples 34 includes a depth of 0.227 mm. In an embodiment, each of the dimples 34 includes a depth of 0.23 mm. In an embodiment, each of the dimples 34 includes a depth of 0.24 mm. In an embodiment, each of the dimples 34 includes a depth of 0.25 mm. In an embodiment, each of the dimples 34 includes a depth of 0.26 mm. In an embodiment, each of the dimples 34 includes a depth of 0.27 mm. In an embodiment, each of the dimples 34 includes a depth of 0.28 mm.

In an embodiment, the liner 32 includes polytetrafluoroethylene (PTFE). In an embodiment, the liner 32 includes PTFE transport and release sheet. In an embodiment, the PTFE transport and release sheet is Steinbach AG PTFE Type 5307. In an embodiment, the liner 32 is configured to form within the frontsheet 16 a plurality of indentations having a size and shape corresponding to those of the plurality of dimples 34.

In an embodiment, FIG. 2C shows a liner 36 including a plurality of dimples 38 formed within a surface thereof. In an embodiment, each of the dimples 38 includes a length of 1.44 mm to 1.52 mm. In an embodiment, a majority of the dimples 38 have a length of 1.44 mm to 1.52 mm. In an embodiment, each of the dimples 38 includes a length of 1.44 mm to 1.51 mm. In an embodiment, each of the dimples 38 includes a length of 1.44 mm to 1.5 mm. In an embodiment, each of the dimples 38 includes a length of 1.44 mm to 1.49 mm. In an embodiment, each of the dimples 38 includes a length of 1.44 mm to 1.48 mm. In an embodiment, each of the dimples 38 includes a length of 1.44 mm to 1.47 mm. In an embodiment, each of the dimples 38 includes a length of 1.44 mm to 1.46 mm. In an embodiment, each of the dimples 38 includes a length of 1.44 mm to 1.45 mm.

In an embodiment, each of the dimples 38 includes a length of 1.45 mm to 1.52 mm. In an embodiment, each of the dimples 38 includes a length of 1.45 mm to 1.51 mm. In an embodiment, each of the dimples 38 includes a length of 1.45 mm to 1.5 mm. In an embodiment, each of the dimples 38 includes a length of 1.45 mm to 1.49 mm. In an embodiment, each of the dimples 38 includes a length of 1.45 mm to 1.48 mm. In an embodiment, each of the dimples 38 includes a length of 1.45 mm to 1.47 mm. In an embodiment, each of the dimples 38 includes a length of 1.45 mm to 1.46 mm.

In an embodiment, each of the dimples 38 includes a length of 1.46 mm to 1.52 mm. In an embodiment, each of the dimples 38 includes a length of 1.46 mm to 1.51 mm. In an embodiment, each of the dimples 38 includes a length of 1.46 mm to 1.5 mm. In an embodiment, each of the dimples 38 includes a length of 1.46 mm to 1.49 mm. In an embodiment, each of the dimples 38 includes a length of 1.46 mm to 1.48 mm. In an embodiment, each of the dimples 38 includes a length of 1.46 mm to 1.47 mm. In an embodiment, each of the dimples 38 includes a length of 1.47 mm to 1.52 mm. In an embodiment, each of the dimples 38 includes a length of 1.47 mm to 1.51 mm. In an embodiment, each of the dimples 38 includes a length of 1.47 mm to 1.5 mm. In an embodiment, each of the dimples 38 includes a length of 1.47 mm to 1.49 mm. In an embodiment, each of the dimples 38 includes a length of 1.47 mm to 1.48 mm.

In an embodiment, each of the dimples 38 includes a length of 1.48 mm to 1.52 mm. In an embodiment, each of the dimples 38 includes a length of 1.48 mm to 1.51 mm. In an embodiment, each of the dimples 38 includes a length of 1.48 mm to 1.5 mm. In an embodiment, each of the dimples 38 includes a length of 1.48 mm to 1.49 mm. In an embodiment, each of the dimples 38 includes a length of 1.49 mm to 1.52 mm. In an embodiment, each of the dimples 38 includes a length of 1.49 mm to 1.51 mm. In an embodiment, each of the dimples 38 includes a length of 1.49 mm to 1.5 mm. In an embodiment, each of the dimples 38 includes a length of 1.5 mm to 1.52 mm. In an embodiment, each of the dimples 38 includes a length of 1.5 mm to 1.51 mm. In an embodiment, each of the dimples 38 includes a length of 1.51 mm to 1.52 mm.

In an embodiment, each of the dimples 38 includes a length of 1.44 mm. In an embodiment, each of the dimples 38 includes a length of 1.45 mm. In an embodiment, each of the dimples 38 includes a length of 1.46 mm. In an embodiment, each of the dimples 38 includes a length of 1.47 mm. In an embodiment, each of the dimples 38 includes a length of 1.48 mm. In an embodiment, each of the dimples 38 includes a length of 1.49 mm. In an embodiment, each of the dimples 38 includes a length of 1.5 mm. In an embodiment, each of the dimples 38 includes a length of 1.51 mm. In an embodiment, each of the dimples 38 includes a length of 1.52 mm.

In an embodiment, each of the dimples 38 includes a width of 3.19 mm to 3.24 mm. In an embodiment, a majority of the dimples 38 have a width of 3.19 mm to 3.24 mm. In an embodiment, each of the dimples 38 includes a width of 3.19 mm to 3.23 mm. In an embodiment, each of the dimples 38 includes a width of 3.19 mm to 3.22 mm. In an embodiment, each of the dimples 38 includes a width of 3.19 mm to 3.21 mm. In an embodiment, each of the dimples 38 includes a width of 3.19 mm to 3.20 mm. In an embodiment, each of the dimples 38 includes a width of 3.2 mm to 3.24 mm. In an embodiment, each of the dimples 38 includes a width of 3.2 mm to 3.23 mm. In an embodiment, each of the dimples 38 includes a width of 3.2 mm to 3.22 mm. In an embodiment, each of the dimples 38 includes a width of 3.2 mm to 3.21 mm. In an embodiment, each of the dimples 38 includes a width of 3.21 mm to 3.24 mm. In an embodiment, each of the dimples 38 includes a width of 3.21 mm to 3.23 mm. In an embodiment, each of the dimples 38 includes a width of 3.21 mm to 3.22 mm. In an embodiment, each of the dimples 38 includes a width of 3.22 mm to 3.24 mm. In an embodiment, each of the dimples 38 includes a width of 3.22 mm to 3.23 mm. In an embodiment, each of the dimples 38 includes a width of 3.23 mm to 3.24 mm.

In an embodiment, each of the dimples 38 includes a width of 3.19 mm. In an embodiment, each of the dimples 38 includes a width of 3.2 mm. In an embodiment, each of the dimples 38 includes a width of 3.21 mm. In an embodiment, each of the dimples 38 includes a width of 3.22 mm. In an embodiment, each of the dimples 38 includes a width of 3.23 mm. In an embodiment, each of the dimples 38 includes a width of 3.24 mm.

In an embodiment, each of the dimples 38 includes a depth of 0.19 mm to 0.32 mm. In an embodiment, a majority of the dimples 38 have a depth of 0.19 mm to 0.32 mm. In an embodiment, each of the dimples 38 includes a depth of 0.19 mm to 0.31 mm. In an embodiment, each of the dimples 38 includes a depth of 0.19 mm to 0.3 mm. In an embodiment, each of the dimples 38 includes a depth of 0.19 mm to 0.29 mm. In an embodiment, each of the dimples 38 includes a depth of 0.19 mm to 0.28 mm. In an embodiment, each of the dimples 38 includes a depth of 0.19 mm to 0.27 mm. In an embodiment, each of the dimples 38 includes a depth of 0.19 mm to 0.26 mm. In an embodiment, each of the dimples 38 includes a depth of 0.19 mm to 0.25 mm. In an embodiment, each of the dimples 38 includes a depth of 0.19 mm to 0.24 mm. In an embodiment, each of the dimples 38 includes a depth of 0.19 mm to 0.23 mm. In an embodiment, each of the dimples 38 includes a depth of 0.19 mm to 0.22 mm. In an embodiment, each of the dimples 38 includes a depth of 0.19 mm to 0.21 mm. In an embodiment, each of the dimples 38 includes a depth of 0.19 mm to 0.2 mm.

In an embodiment, each of the dimples 38 includes a depth of 0.2 mm to 0.32 mm. In an embodiment, each of the dimples 38 includes a depth of 0.2 mm to 0.31 mm. In an embodiment, each of the dimples 38 includes a depth of 0.2 mm to 0.3 mm. In an embodiment, each of the dimples 38 includes a depth of 0.2 mm to 0.29 mm. In an embodiment, each of the dimples 38 includes a depth of 0.2 mm to 0.28 mm. In an embodiment, each of the dimples 38 includes a depth of 0.2 mm to 0.27 mm. In an embodiment, each of the dimples 38 includes a depth of 0.2 mm to 0.26 mm. In an embodiment, each of the dimples 38 includes a depth of 0.2 mm to 0.25 mm. In an embodiment, each of the dimples 38 includes a depth of 0.2 mm to 0.24 mm. In an embodiment, each of the dimples 38 includes a depth of 0.2 mm to 0.23 mm. In an embodiment, each of the dimples 38 includes a depth of 0.2 mm to 0.22 mm. In an embodiment, each of the dimples 38 includes a depth of 0.2 mm to 0.21 mm.

In an embodiment, each of the dimples 38 includes a depth of 0.21 mm to 0.32 mm. In an embodiment, each of the dimples 38 includes a depth of 0.21 mm to 0.31 mm. In an embodiment, each of the dimples 38 includes a depth of 0.21 mm to 0.3 mm. In an embodiment, each of the dimples 38 includes a depth of 0.21 mm to 0.29 mm. In an embodiment, each of the dimples 38 includes a depth of 0.21 mm to 0.28 mm. In an embodiment, each of the dimples 38 includes a depth of 0.21 mm to 0.27 mm. In an embodiment, each of the dimples 38 includes a depth of 0.21 mm to 0.26 mm. In an embodiment, each of the dimples 38 includes a depth of 0.21 mm to 0.25 mm. In an embodiment, each of the dimples 38 includes a depth of 0.21 mm to 0.24 mm. In an embodiment, each of the dimples 38 includes a depth of 0.21 mm to 0.23 mm. In an embodiment, each of the dimples 38 includes a depth of 0.21 mm to 0.22 mm.

In an embodiment, each of the dimples 38 includes a depth of 0.22 mm to 0.32 mm. In an embodiment, each of the dimples 38 includes a depth of 0.22 mm to 0.31 mm. In an embodiment, each of the dimples 38 includes a depth of 0.22 mm to 0.3 mm. In an embodiment, each of the dimples 38 includes a depth of 0.22 mm to 0.29 mm. In an embodiment, each of the dimples 38 includes a depth of 0.22 mm to 0.28 mm. In an embodiment, each of the dimples 38 includes a depth of 0.22 mm to 0.27 mm. In an embodiment, each of the dimples 38 includes a depth of 0.22 mm to 0.26 mm. In an embodiment, each of the dimples 38 includes a depth of 0.22 mm to 0.25 mm. In an embodiment, each of the dimples 38 includes a depth of 0.22 mm to 0.24 mm. In an embodiment, each of the dimples 38 includes a depth of 0.22 mm to 0.23 mm.

In an embodiment, each of the dimples 38 includes a depth of 0.23 mm to 0.32 mm. In an embodiment, each of the dimples 38 includes a depth of 0.23 mm to 0.31 mm. In an embodiment, each of the dimples 38 includes a depth of 0.23 mm to 0.3 mm. In an embodiment, each of the dimples 38 includes a depth of 0.23 mm to 0.29 mm. In an embodiment, each of the dimples 38 includes a depth of 0.23 mm to 0.28 mm. In an embodiment, each of the dimples 38 includes a depth of 0.23 mm to 0.27 mm. In an embodiment, each of the dimples 38 includes a depth of 0.23 mm to 0.26 mm. In an embodiment, each of the dimples 38 includes a depth of 0.23 mm to 0.25 mm. In an embodiment, each of the dimples 38 includes a depth of 0.23 mm to 0.24 mm.

In an embodiment, each of the dimples 38 includes a depth of 0.24 mm to 0.32 mm. In an embodiment, each of the dimples 38 includes a depth of 0.24 mm to 0.31 mm. In an embodiment, each of the dimples 38 includes a depth of 0.24 mm to 0.3 mm. In an embodiment, each of the dimples 38 includes a depth of 0.24 mm to 0.29 mm. In an embodiment, each of the dimples 38 includes a depth of 0.24 mm to 0.28 mm. In an embodiment, each of the dimples 38 includes a depth of 0.24 mm to 0.27 mm. In an embodiment, each of the dimples 38 includes a depth of 0.24 mm to 0.26 mm. In an embodiment, each of the dimples 38 includes a depth of 0.24 mm to 0.25 mm.

In an embodiment, each of the dimples 38 includes a depth of 0.25 mm to 0.32 mm. In an embodiment, each of the dimples 38 includes a depth of 0.25 mm to 0.31 mm. In an embodiment, each of the dimples 38 includes a depth of 0.25 mm to 0.3 mm. In an embodiment, each of the dimples 38 includes a depth of 0.25 mm to 0.29 mm. In an embodiment, each of the dimples 38 includes a depth of 0.25 mm to 0.28 mm. In an embodiment, each of the dimples 38 includes a depth of 0.25 mm to 0.27 mm. In an embodiment, each of the dimples 38 includes a depth of 0.25 mm to 0.26 mm.

In an embodiment, each of the dimples 38 includes a depth of 0.26 mm to 0.32 mm. In an embodiment, each of the dimples 38 includes a depth of 0.26 mm to 0.31 mm. In an embodiment, each of the dimples 38 includes a depth of 0.26 mm to 0.3 mm. In an embodiment, each of the dimples 38 includes a depth of 0.26 mm to 0.29 mm. In an embodiment, each of the dimples 38 includes a depth of 0.26 mm to 0.28 mm. In an embodiment, each of the dimples 38 includes a depth of 0.26 mm to 0.27 mm.

In an embodiment, each of the dimples 38 includes a depth of 0.27 mm to 0.32 mm. In an embodiment, each of the dimples 38 includes a depth of 0.27 mm to 0.31 mm. In an embodiment, each of the dimples 38 includes a depth of 0.27 mm to 0.3 mm. In an embodiment, each of the dimples 38 includes a depth of 0.27 mm to 0.29 mm. In an embodiment, each of the dimples 38 includes a depth of 0.27 mm to 0.28 mm. In an embodiment, each of the dimples 38 includes a depth of 0.28 mm to 0.32 mm. In an embodiment, each of the dimples 38 includes a depth of 0.28 mm to 0.31 mm. In an embodiment, each of the dimples 38 includes a depth of 0.28 mm to 0.3 mm. In an embodiment, each of the dimples 38 includes a depth of 0.28 mm to 0.29 mm.

In an embodiment, each of the dimples 38 includes a depth of 0.29 mm to 0.32 mm. In an embodiment, each of the dimples 38 includes a depth of 0.29 mm to 0.31 mm. In an embodiment, each of the dimples 38 includes a depth of 0.29 mm to 0.3 mm. In an embodiment, each of the dimples 38 includes a depth of 0.3 mm to 0.32 mm. In an embodiment, each of the dimples 38 includes a depth of 0.3 mm to 0.31 mm. In an embodiment, each of the dimples 38 includes a depth of 0.31 mm to 0.32 mm.

In an embodiment, each of the dimples 38 includes a depth of 0.19 mm. In an embodiment, each of the dimples 38 includes a depth of 0.2 mm. In an embodiment, each of the dimples 38 includes a depth of 0.21 mm. In an embodiment, each of the dimples 38 includes a depth of 0.22 mm. In an embodiment, each of the dimples 38 includes a depth of 0.23 mm. In an embodiment, each of the dimples 38 includes a depth of 0.24 mm. In an embodiment, each of the dimples 38 includes a depth of 0.25 mm. In an embodiment, each of the dimples 38 includes a depth of 0.252 mm. In an embodiment, each of the dimples 38 includes a depth of 0.26 mm. In an embodiment, each of the dimples 38 includes a depth of 0.27 mm. In an embodiment, each of the dimples 38 includes a depth of 0.28 mm. In an embodiment, each of the dimples 38 includes a depth of 0.29 mm. In an embodiment, each of the dimples 38 includes a depth of 0.3 mm. In an embodiment, each of the dimples 38 includes a depth of 0.31 mm. In an embodiment, each of the dimples 38 includes a depth of 0.32 mm.

In an embodiment, the liner 36 includes a polymer coated fiber reinforced membrane. In an embodiment, the liner 36 is a polytetrafluoroethylene (PTFE) coated fiber reinforced membrane. In an embodiment, the liner 36 is Xiya A membrane. In an embodiment, the liner 36 is configured to form within the frontsheet 16 a plurality of indentations having a size and shape corresponding to those of the plurality of dimples 38.

In another embodiment, the indentations are created by embossing a portion of the frontsheet 16. In another embodiment, the indentations are created by embossing the polymer layer 20 of the frontsheet 16.

Still referring to FIGS. 2A through 2C, in an embodiment, each of the dimples 30 is oblong in shape. In an embodiment, a majority of the dimples 30 is oblong in shape. In an embodiment, the dimples 30 are arranged in and form a grain pattern. In an embodiment, the grain pattern extends in a direction Y. In an embodiment, each of the dimples 34 is oblong in shape. In an embodiment, a majority of the dimples 34 is oblong in shape. In an embodiment, the dimples 34 are arranged in and form a grain pattern. In an embodiment, the grain pattern extends in a direction Y. In an embodiment, each of the dimples 38 is oblong in shape. In an embodiment, a majority of the dimples 38 is oblong in shape. In an embodiment, the dimples 38 are arranged in and form a grain pattern. In an embodiment, the grain pattern extends in a direction Y.

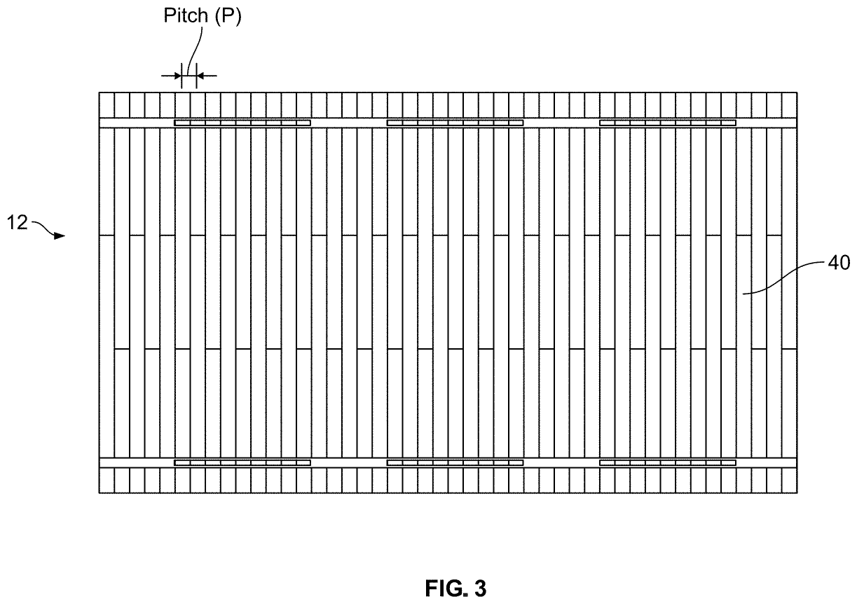

Referring to FIG. 3, the at least one solar cell 12 includes a plurality of cell fingers 40. In an embodiment, the plurality of cell fingers 40 are arranged in and form a grain pattern. In an embodiment, the grain pattern of the plurality of cell fingers 40 extends in a direction Y. In an embodiment, the cell fingers 40 include a pitch P (the distance from a center, longitudinal axis of one of the cell fingers 40 to a center, longitudinal axis of another adjacent one of the cell fingers 40).

In an embodiment, the cell fingers 40 include a pitch of 1.0 mm to 1.5 mm. In another embodiment, the cell fingers 40 include a pitch of 1.0 mm to 1.4 mm. In another embodiment, the cell fingers 40 include a pitch of 1.0 mm to 1.3 mm. In another embodiment, the cell fingers 40 include a pitch of 1.0 mm to 1.2 mm. In another embodiment, the cell fingers 40 include a pitch of 1.0 mm to 1.1 mm. In an embodiment, the cell fingers 40 include a pitch of 1.1 mm to 1.5 mm. In another embodiment, the cell fingers 40 include a pitch of 1.1 mm to 1.4 mm. In another embodiment, the cell fingers 40 include a pitch of 1.1 mm to 1.3 mm. In another embodiment, the cell fingers 40 include a pitch of 1.1 mm to 1.2 mm. In an embodiment, the cell fingers 40 include a pitch of 1.2 mm to 1.5 mm. In another embodiment, the cell fingers 40 include a pitch of 1.2 mm to 1.4 mm. In another embodiment, the cell fingers 40 include a pitch of 1.2 mm to 1.3 mm. In an embodiment, the cell fingers 40 include a pitch of 1.3 mm to 1.5 mm. In another embodiment, the cell fingers 40 include a pitch of 1.3 mm to 1.4 mm. In an embodiment, the cell fingers 40 include a pitch of 1.4 mm to 1.5 mm.

In an embodiment, the photovoltaic module 10 is configured to be installed on a roof deck. In an embodiment, a system includes a plurality of the photovoltaic module 10. In an embodiment, when the photovoltaic module 10 is installed on a roof deck of a structure, the photovoltaic module 10 module is viewable. In some embodiments, the term “viewable” as used herein means visible or capable of being seen and, with respect to some embodiments of the photovoltaic module 10, visible or capable of being seen from a vantage point of an individual located at a ground level of the structure.

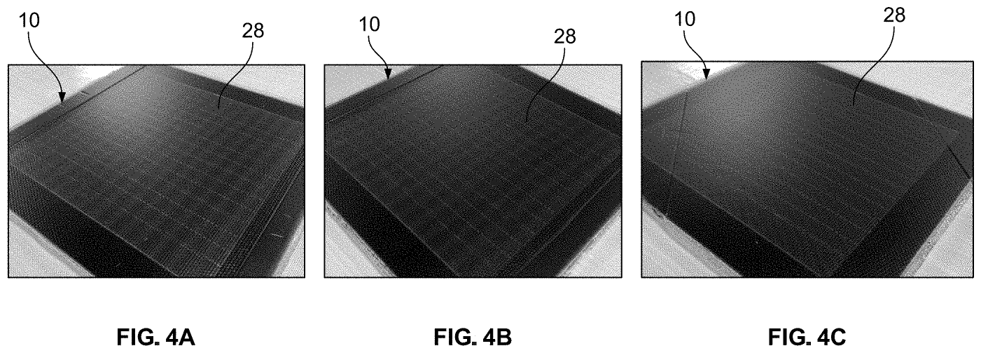

FIGS. 4A through 4C show embodiments of the photovoltaic module 10 including the liner 28. Referring to FIG. 4A, in an embodiment, the grain pattern of the liner 28 is positioned parallel to (zero (0) degrees relative to) the grain pattern of the cell fingers 40 of the at least one solar cell 12 when the liner 28 overlays the polymer layer 20 to form a plurality of indentations within the frontsheet 16. In an embodiment, an interference fringe pattern between the plurality of indentations and cell fingers 40 is viewable.

Referring to FIG. 4B, in an embodiment, the grain pattern of the liner 28 is positioned perpendicular to (90 degrees relative to) the grain pattern of the cell fingers 40 of the at least one solar cell 12 when the liner 28 overlays the polymer layer 20 to form a plurality of indentations within the frontsheet 16. In an embodiment, an interference fringe pattern between the plurality of indentations and the cell fingers 40 is viewable.

Referring to FIG. 4C, in an embodiment, the grain pattern of the liner 28 is positioned 45 degrees relative to the grain pattern of the cell fingers 40 of the at least one solar cell 12 when the liner 28 overlays the polymer layer 20 to form a plurality of indentations within the frontsheet 16. In an embodiment, an interference fringe pattern between the plurality of indentations and cell fingers 40 is faint and slightly viewable.

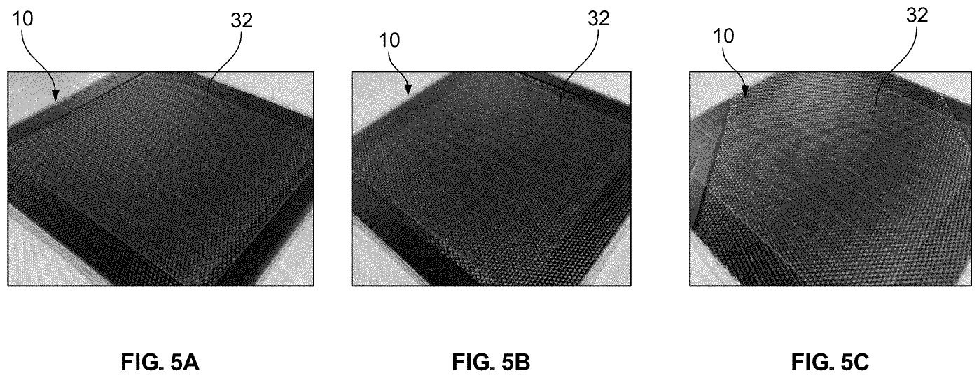

FIGS. 5A through 5C show embodiments of the photovoltaic module 10 including the liner 32. Referring to FIG. 5A, in an embodiment, the grain pattern of the liner 32 is positioned parallel to (zero (0) degrees relative to) the grain pattern of the cell fingers 40 of the at least one solar cell 12 when the liner 32 overlays the polymer layer 20 to form a plurality of indentations within the frontsheet 16. In an embodiment, there is no viewable interference fringe pattern between the plurality of indentations and the cell fingers 40.

Referring to FIG. 5B, in an embodiment, the grain pattern of the liner 32 is positioned perpendicular to (90 degrees relative to) the grain pattern of the cell fingers 40 of the at least one solar cell 12 when the liner 32 overlays the polymer layer 20 to form a plurality of indentations within the frontsheet 16. In an embodiment, there is no viewable interference fringe pattern between the plurality of indentations and the cell fingers 40.

Referring to FIG. 5C, in an embodiment, the grain pattern of the liner 32 is positioned 45 degrees relative to the grain pattern of the cell fingers 40 of the at least one solar cell 12 when the liner 32 overlays the polymer layer 20 to form a plurality of indentations within the frontsheet 16. In an embodiment, there is no viewable interference fringe pattern between the plurality of indentations and the cell fingers 40.

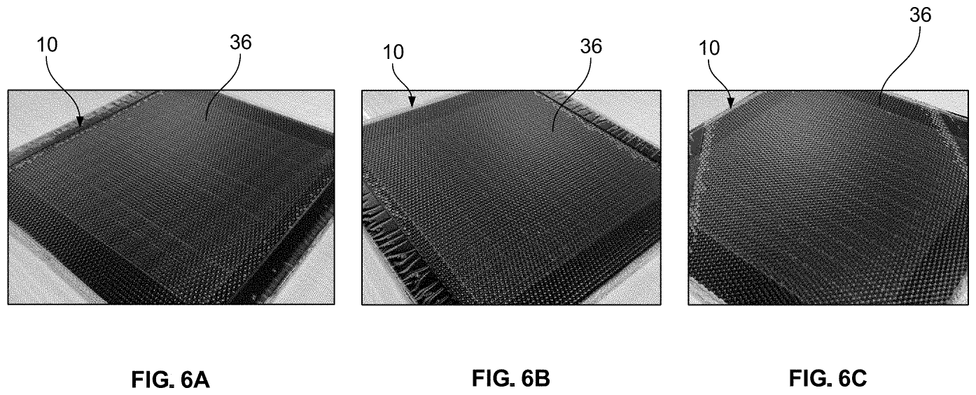

FIGS. 6A through 6C show embodiments of the photovoltaic module 10 including the liner 36. Referring to FIG. 6A, in an embodiment, the grain pattern of the liner 36 is positioned parallel to (zero (0) degrees relative to) the grain pattern of the cell fingers 40 of the at least one solar cell 12 when the liner 36 overlays the polymer layer 20 to form a plurality of indentations within the frontsheet 16. In an embodiment, an interference fringe pattern between the plurality of indentations and the cell fingers 40 is viewable.

Referring to FIG. 6B, in an embodiment, the grain pattern of the liner 36 is positioned perpendicular to (90 degrees relative to) the grain pattern of the cell fingers 40 of the at least one solar cell 12 when the liner 36 overlays the polymer layer 20 to form the plurality of indentations within the frontsheet 16. In an embodiment, there is no viewable interference fringe pattern between the plurality of indentations and the cell fingers 40.

Referring to FIG. 6C, in an embodiment, the grain pattern of the liner 36 is positioned 45 degrees relative to the grain pattern of the cell fingers 40 of the at least one solar cell 12 when the liner 36 overlays the polymer layer 20 to form the plurality of indentations within the frontsheet 16. In an embodiment, there is no viewable interference fringe pattern between the plurality of indentations and the cell fingers 40.

While a number of embodiments of the present invention have been described, it is understood that these embodiments are illustrative only, and not restrictive, and that many modifications may become apparent to those of ordinary skill in the art. Further still, the various steps may be carried out in any desired order (and any desired steps may be added and/or any desired steps may be eliminated).

What is claimed is:

1. A photovoltaic module, comprising:
at least one solar cell,
wherein the at least one solar cell includes a plurality of cell fingers,
wherein the plurality of cell fingers are arranged in a first grain pattern extending in a first direction;
an encapsulant encapsulating the at least one solar cell; and
a frontsheet juxtaposed with the encapsulant,
wherein the frontsheet includes
a glass layer having a first surface,
a polymer layer having a first surface and a second surface opposite the first surface of the polymer layer, wherein the second surface of the polymer layer is attached to the first surface of the glass layer,
wherein the first surface of the polymer layer includes a plurality of indentations, and
wherein the plurality of indentations is arranged in a second grain pattern extending in a second direction,
wherein the first surface of the polymer layer forms an upper surface of the photovoltaic module, and
wherein the arrangement of the second grain pattern relative to the arrangement of the first grain pattern imparts no viewable interference pattern of the photovoltaic module.

2. The photovoltaic module of claim 1, wherein the cell fingers have a pitch of 1.0 mm to 1.5 mm.

3. The photovoltaic module of claim 1, wherein a majority of the plurality of indentations have a length of 1.2 mm to 1.4 mm.

4. The photovoltaic module of claim 3, wherein a majority of the plurality of indentations have a width of 2.85 mm to 2.95 mm.

5. The photovoltaic module of claim 4, wherein a majority of the plurality of indentations includes a depth of 0.17 mm to 0.28 mm.

6. The photovoltaic module of claim 5, wherein the second direction is zero degrees relative to the first direction.

7. The photovoltaic module of claim 5, wherein the second direction is 45 degrees relative to the first direction.

8. The photovoltaic module of claim 5, wherein the second direction is 90 degrees relative to the first direction.

9. The photovoltaic module of claim 1, wherein a majority of the plurality of indentations have a length of 1.44 mm to 1.52 mm.

10. The photovoltaic module of claim 9, wherein a majority of the plurality of indentations have a width of 3.19 mm to 3.24 mm.

11. The photovoltaic module of claim 10, wherein a majority of the plurality of indentations have a depth of 0.19 mm to 0.32 mm.

12. The photovoltaic module of claim 11, wherein the second direction is zero degrees relative to the first direction.

13. The photovoltaic module of claim 11, wherein the second direction is 45 degrees relative to the first direction.

14. The photovoltaic module of claim 11, wherein the second direction is 90 degrees relative to the first direction.

15. A system, comprising:
a plurality of photovoltaic modules installed on a roof deck, wherein each of the photovoltaic modules includes
at least one solar cell,
wherein the at least one solar cell includes a plurality of cell fingers,
wherein the plurality of cell fingers are arranged in a first grain pattern extending in a first direction;
an encapsulant encapsulating the at least one solar cell; and
a frontsheet juxtaposed with the encapsulant,
wherein the frontsheet includes
a glass layer having a first surface,
a polymer layer having a first surface and a second surface opposite the first surface of the polymer layer, wherein the second surface of the polymer layer is attached to the first surface of the glass layer,
wherein the first surface of the polymer layer includes a plurality of indentations, and
wherein the plurality of indentations is arranged in a second grain pattern extending in a second direction,
wherein the first surface of the polymer layer forms an upper surface of the photovoltaic module, and
wherein the arrangement of the second grain pattern relative to the arrangement of the first grain pattern imparts no viewable interference pattern of the photovoltaic modules.

16. The system of claim 15, wherein the cell fingers include a pitch of 1.0 mm to 1.5 mm.

17. The system of claim 15, wherein a majority of the plurality of indentations have a length of 1.2 mm to 1.52 mm, wherein the majority of the plurality of indentations have a width of 2.85 mm to 3.24 mm, and wherein the majority of the plurality of indentations have a depth of 0.17 mm to 0.32 mm.

18. The system of claim 17, wherein the second direction is zero degrees relative to the first direction.

19. The system of claim 17, wherein the second direction is 45 degrees relative to the first direction.

20. The system of claim 17, wherein the second direction is 90 degrees relative to the first direction.
